(19) United States
(12) Patent Application Publication
(10) Pub. No.: US 2026/0164991 A1
(43) Pub. Date: Jun. 11, 2026

(54) METHOD FOR MANUFACTURING DISPLAY DEVICE

(71) Applicant: Samsung Display Co., Ltd., Yongin-si (KR)

(72) Inventors: Ji Hoon SONG, Yongin-si (KR); So Hyun KIM, Yongin-si (KR); Jong Suk LEE, Yongin-si (KR); Kwan Bae KONG, Yongin-si (KR); Yong Hwan YOON, Yongin-si (KR)

(21) Appl. No.: 19/179,820

(22) Filed: Apr. 15, 2025

(30) Foreign Application Priority Data
Jun. 26, 2024 (KR) 10-2024-0083584
Aug. 28, 2024 (KR) 10-2024-0115875

(51) Int. Cl. H10K 59/80; H10K 59/12

(52) U.S. Cl. CPC H10K 59/873; H10K 59/1201

(57) ABSTRACT

A method for manufacturing a display device includes preparing a display panel having a flat plate shape configured to emit light for image display; preparing a guide member including a main support area overlapping the display panel and two or more sub-wing areas extending from an edge of the main support area; attaching the display panel onto the guide member; attaching the display panel onto the guide member; transforming the display panel from the flat plate shape into a shape with a curved edge by using the guide member and the mold member; disposing a transparent adhesive material and a cover window on the display panel; transforming the guide member; curing the transparent adhesive material to form a transparent adhesive layer that fixes the display panel to the cover window; and separating the guide member from the display panel.

### CROSS-REFERENCE TO RELATED APPLICATION

The present application claims priority to and the benefit of Korean Patent Application No. 10-2024-0083584, filed on Jun. 26, 2024, in the Korean Intellectual Property Office, and Korean Patent Application No. 10-2024-0115875, filed on Aug. 28, 2024, in the Korean Intellectual Property Office, the entire disclosures of these two applications are incorporated herein by reference.

### BACKGROUND

### 1. Field

Embodiments of the present disclosure relate to a method for manufacturing a display device.

### 2. Description of the Related Art

With the advance of information society, it is desirable for display devices to be capable of displaying images in various ways and in various devices. For example, display devices are employed in various electronic devices such as smartphones, digital cameras, laptop computers, navigation devices, and/or smart televisions.

A display device may be a flat panel display device such as a liquid crystal display device, a field emission display device, or a light emitting display device. Examples of a light emitting display device may include an organic light emitting display device including organic light emitting elements, an inorganic light emitting display device including inorganic light emitting elements such as inorganic semiconductors, and a micro light emitting display device including micro light emitting elements.

Organic light emitting display devices display an image using light emitting elements, each light emitting element including a light emitting layer made of (e.g., composed of) an organic light emitting material. The organic light emitting display device implements image display using a self-light emitting element, and thus may have relatively superior performance in power consumption, response speed, luminous efficiency, luminance, and/or wide viewing angle compared to other display devices.

In display devices, a display surface from which light is emitted may include a display area in which an image is displayed, and a non-display area around the display area. Emission areas emitting light with respective luminances and colors may be arranged in the display area.

The above information disclosed in this Background section is intended to enhance understanding of the background of the disclosure and may contain information that does not constitute prior art.

### SUMMARY

When the display area is arranged wider (e.g., includes a larger portion of the width of the display surface of the display device), the area of the display device from which light is emitted is widened, thus improving aesthetics and compatibility with one or more suitable electronic devices. Therefore, measures to reduce the width of the non-display area in the display surface have been researched and developed.

However, because there are wires and elements that are essentially arranged in the non-display area (e.g., wires and elements essential to and/or desirable for the function of the display device), there is a limit to the amount by which the width of the non-display area may be reduced.

In view of the above, aspects of one or more embodiments of the present disclosure are directed toward a method for manufacturing a display device in which the width of a non-display area that is visually recognized in a front direction facing (e.g., opposite to) a display surface may be reduced by transforming the edge of the display area into a curved shape.

However, aspects of the present disclosure are not restricted to the one set forth herein. The above and other aspects will be set forth in part in the description which follows and, in part, will be apparent from the description, or may be learned by practice of the presented embodiments of the disclosure.

According to one or more embodiments of the present disclosure, a method for manufacturing a display device includes preparing a display panel having a flat plate shape configured to emit light for image display; preparing a guide member including a main support area facing (e.g., overlapping) the display panel and two or more sub-wing areas extending from an edge of the main support area; attaching the display panel onto the guide member; placing a mold member below the guide member; transforming the display panel from the flat plate shape into a shape with a curved edge by using the guide member and the mold member; disposing a transparent adhesive material and a cover window on the display panel; transforming the guide member; curing the transparent adhesive material to form a transparent adhesive layer that fixes the display panel to the cover window; and separating the guide member from the display panel.

According to one or more embodiments, in the preparing of the display panel, the display panel may include a substrate; a circuit layer arranged on the substrate; and an element layer arranged on the circuit layer. After the transforming of the display panel, the substrate may include a flat display area having a planar shape; and a curved area arranged around the flat display area and having a curved shape. The curved area may include a peripheral display area arranged around the flat display area and a non-display area arranged around the peripheral display area. Emission areas emitting the light may be arranged in the flat display area and the peripheral display area. The element layer may include light emitting elements arranged in the emission areas.

In one or more embodiments, the two or more sub-wing areas may include one or more first sub-wing areas extending from one edge of the main support area; and one or more second sub-wing areas extending from another edge of the main support area and that is opposite to (e.g., facing) the one or more first sub-wing areas. The transforming of the display panel may include a process of pulling the two or more sub-wing areas of the guide member toward an underside of the mold member.

In one or more embodiments, in the preparing of the guide member, the guide member may include a guide support layer including the main support area and the two or more sub-wing areas; a guide adhesive layer arranged on the guide support layer; and a cover layer covering the two or more sub-wing areas. In the attaching of the display panel onto the guide member, the display panel may be attached to the main support area of the guide adhesive layer. In the transforming of the guide member, the two or more sub-wing areas may be accommodated under the guide support layer and overlap the main support area.

The guide adhesive layer may contain (include) a curing material different from that of the transparent adhesive layer.

In one or more embodiments, the separating of the guide member from the display panel may include softening the guide adhesive layer, and delaminating the guide adhesive layer and the guide support layer from the display panel.

In one or more embodiments, in the preparing of the guide member, the guide member may include a guide support layer including the main support area and the two or more sub-wing areas; a guide adhesive layer arranged on the main support area of the guide support layer; an additional support layer arranged on the guide adhesive layer; and an additional adhesive layer arranged on the additional support layer. In the attaching of the display panel onto the guide member, the display panel may be attached to the additional adhesive layer.

In one or more embodiments, the guide adhesive layer may contain (include) a curing material different from that of the transparent adhesive layer. The additional adhesive layer may contain (include) a curing material different from that of each of the transparent adhesive layer and the guide adhesive layer.

In the transforming of the guide member, by softening the guide adhesive layer, the guide adhesive layer and the guide support layer are delaminated.

In one or more embodiments, the separating of the guide member from the display panel may include softening the additional adhesive layer, and delaminating the additional adhesive layer and the additional support layer from the display panel.

In one or more embodiments, the substrate may include a main region including the flat display area and the curved area, and an edge of the main region may include a first side and a second side extending in a first direction and opposing each other in a second direction intersecting the first direction; a third side and a fourth side extending in the second direction and opposing each other in the first direction; and corners connecting one of the first and/or second sides to one of the third and/or fourth sides. Each of the additional support layer and the additional adhesive layer may include residual portions that face (overlap) some areas of the main region adjacent to the corners; and a dummy portion that faces (overlaps) a remaining area excluding the some areas of the main region and is spaced and/or apart (e.g., spaced apart or separated) from the residual portions. The guide adhesive layer may contain (include) a curing material different from that of the transparent adhesive layer. The dummy portion of the additional adhesive layer may contain (include) the same curing material as that of the guide adhesive layer. The residual portions of the additional adhesive layer may contain (include) a curing material different from that of each of the transparent adhesive layer and the guide adhesive layer.

In one or more embodiments, the transforming of the guide member may include softening the guide adhesive layer and the dummy portion of the additional adhesive layer, and delaminating the guide adhesive layer, the guide support layer, the dummy portion of the additional adhesive layer and the dummy portion of the additional support layer from the display panel.

In one or more embodiments, the separating of the guide member from the display panel may include softening the residual portions of the additional adhesive layer, and delaminating the residual portions of each of the additional adhesive layer and the additional support layer from the display panel.

In one or more embodiments, the flat display area may include a fifth side and a sixth side extending in the first direction and opposing each other in the first direction; and a seventh side and an eighth side extending in the second direction and opposing each other in the first direction. The curved area may include a first side area between the first side and the fifth side; a second side area between the second side and the sixth side; a third side area between the third side and the seventh side; a fourth side area between the fourth side and the eighth side; a first corner area in contact with a vertex between the fifth side and the seventh side and arranged between the first side area and the third side area; a second corner area in contact with a vertex between the sixth side and the seventh side and arranged between the second side area and the third side area; a third corner area in contact with a vertex between the sixth side and the eighth side and arranged between the second side area and the fourth side area; and a fourth corner area in contact with a vertex between the fifth side and the eighth side and arranged between the first side area and the fourth side area.

According to one or more embodiments, the residual portions may face (overlap) the first corner area, the second corner area, the third corner area, and the fourth corner area.

According to one or more embodiments of the present disclosure, a method for manufacturing a display device includes preparing a display panel having a flat plate shape that is configured to emit light for image display; preparing a guide member including a main support area facing (overlapping) the display panel and two or more sub-wing areas extending from an edge of the main support area; attaching the display panel onto the guide member; placing a mold member below the guide member; transforming the display panel from the flat plate shape into a shape with a curved edge by using the guide member and the mold member; disposing a transparent adhesive material and a cover window on the display panel; transforming the guide member; curing the transparent adhesive material to form a transparent adhesive layer that fixes the display panel to the cover window; and separating the guide member from the display panel. In the preparing of the guide member, the guide member includes a guide support layer including the main support area and the two or more sub-wing areas; and a guide adhesive layer arranged on the main support area of the guide support layer. The guide adhesive layer contains (includes) a curing material different from that of the transparent adhesive layer.

According to one or more embodiments, the guide adhesive layer may further be arranged on the two or more sub-wing areas of the guide support layer. The guide member may further include a cover layer covering the two or more sub-wing areas. In the transforming of the guide member, the two or more sub-wing areas of the guide member may be accommodated under the guide support layer and overlap the main support area.

According to one or more embodiments, the guide member may further include an additional support layer arranged on the guide adhesive layer; and an additional adhesive layer arranged on the additional support layer. In the attaching of the display panel onto the guide member, the display panel may be attached to the additional adhesive layer.

According to one or more embodiments, the additional adhesive layer may include (e.g., contain) a curing material different from that of each of the transparent adhesive layer and the guide adhesive layer. The transforming of the guide member may include softening the guide adhesive layer, and delaminating the guide adhesive layer and the guide support layer from the display panel.

According to one or more embodiments, in the preparing of the display panel, the display panel may include a substrate; a circuit layer arranged on the substrate; and an element layer arranged on the circuit layer. After the transforming of the display panel, the substrate may include a flat display area having a planar shape; and a curved area arranged around the flat display area and having a curved shape. The curved area may include a peripheral display area arranged around the flat display area; and a non-display area arranged around the peripheral display area. Emission areas to emit the light may be arranged in the flat display area and the peripheral display area. The substrate may include a main region including the flat display area and the curved area, and an edge of the main region may include a first side and a second side extending in a first direction and opposing each other in a second direction intersecting the first direction; a third side and a fourth side extending in the second direction and opposing each other in the first direction; and corners connecting one of the first and/or second sides to one of the third and/or fourth sides. Each of the additional support layer and the additional adhesive layer may include residual portions that face (overlap) some areas of the main region adjacent to the corners; and a dummy portion that faces (overlaps) a remaining area excluding the some areas of the main region and is spaced and/or apart (e.g., spaced apart or separated) from the residual portions. The dummy portion of the additional adhesive layer may include (e.g., contain) the same curing material as that of the guide adhesive layer. The residual portions of the additional adhesive layer may include (e.g., contain) a curing material different from that of each of the transparent adhesive layer and the guide adhesive layer. The transforming of the guide member may include softening the guide adhesive layer and the dummy portion of the additional adhesive layer, and delaminating the guide adhesive layer, the guide support layer, the dummy portion of the additional adhesive layer and the dummy portion of the additional support layer from the display panel.

According to one or more embodiments of the present disclosure an electronic device includes a display panel including: a substrate having a flat display area having a planar shape; and a curved area around the flat display area and having a curved shape; a circuit layer on the substrate; and an element layer on the circuit layer, the element layer including light emitting elements in emission areas to emit light, wherein the curved area includes a peripheral display area around the flat display area and a non-display area around the peripheral display area; and wherein the display panel is manufactured by: preparing the display panel having a flat plate shape that is configured to emit light for image display; preparing a guide member including a main support area overlapping the display panel and two or more sub-wing areas extending from an edge of the main support area; attaching the display panel onto the guide member; placing a mold member below the guide member; transforming the display panel from the flat plate shape into a shape with a curved edge by utilizing the guide member and the mold member; disposing a transparent adhesive material and a cover window on the display panel; transforming the guide member; curing the transparent adhesive material to form a transparent adhesive layer that fixes the display panel to the cover window; and separating the guide member from the display panel.

A method for manufacturing a display device according to one or more embodiments include the steps (e.g., acts or tasks) of transforming a display panel from a flat plate shape to a shape with a curved edge using a guide member and a mold member, disposing a transparent adhesive material and a cover window on the transformed display panel, transforming the guide member, curing the transparent adhesive material, and separating the guide member from the display panel.

In one or more embodiments, the display panel may include a substrate, a circuit layer, and an element layer.

In one or more embodiments, the substrate may include a main region including a display area in which emission areas are arranged, and a non-display area arranged around the display area.

According to one or more embodiments, in the step (e.g., act or task) of transforming the display panel, the display panel attached to the guide member may be transformed into a shape with a curved edge by partially stretching the guide member to correspond to the mold member.

For example, after the step (e.g., act or task) of transforming the display panel, the display area may include a flat display area and a peripheral display area that is arranged around the flat display area and has a curved shape.

As such, as the display area includes the peripheral display area in a curved shape, the non-display area around (e.g., surrounding) the peripheral display area may have a curved shape together with the peripheral display area. For example, the width of the curved non-display area that is visually recognizable from the front direction facing (e.g., opposite to) the display surface may be smaller than the width of the non-display area in an unfolded state.

Therefore, in the display surface of the display device, the width of the display area that is visually recognizable from the front direction may increase, thereby improving the aesthetics and compatibility of the display device.

According to one or more embodiments, in the step (e.g., act or task) of arranging the transparent adhesive material and the cover window, the transparent adhesive material may be arranged on the display panel that has been transformed into a shape with a curved edge, and the cover window having a curved edge may be arranged on the transparent adhesive material.

Then, in the step (e.g., act or task) of curing the transparent adhesive material to form a transparent adhesive layer, an external force corresponding to the shape of the cover window may be applied to the display panel.

According to one or more embodiments, the step (e.g., act or task) of curing the transparent adhesive material may be performed while the guide member attached to the bottom of the display panel remains without being removed.

For example, in a state where the rigidity of the display panel is reinforced by the guide member, an external force for transforming the display panel into the shape of the cover window may be applied to the display panel.

Therefore, even if relatively strong external force is concentrated in a particular area, buckling defects, in which the edge of the display panel become partially unevenly crumpled, may be prevented or reduced due to the rigidity of the display panel reinforced by the guide member.

Accordingly, the method for manufacturing a display device according to one or more embodiments may reduce the defect rate of the display device.

By incorporating a peripheral display area with a curved shape, the non-display area surrounding it also adopts a curved shape, reducing its width when viewed from the front. This increases the visually recognized width of the display area, enhancing the aesthetics and compatibility of the display device. Additionally, the method involves arranging a transparent adhesive material and a cover window with curved edges on the transformed display panel, and curing the adhesive while the guide member remains attached. This reinforcement by the guide member helps prevent buckling defects, even under strong external forces, thereby reducing the defect rate of the display device.

Overall, this approach not only improves the visual appeal and functional compatibility of the display device but also ensures structural integrity during the manufacturing process, leading to higher quality and reliability.

However, effects according to one or more embodiments of the present disclosure are not limited to those above and one or more suitable other effects are incorporated herein.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a perspective view illustrating a display device according to one or more embodiments of the present disclosure;

FIG. 2 is a cross-sectional view taken along the line A-A′ of FIG. 1, according to one or more embodiments of the present disclosure;

FIG. 3 is a cross-sectional view showing the display panel taken along the line B-B′ of FIG. 1, according to one or more embodiments of the present disclosure;

FIG. 4 is a plan view showing the substrate of FIG. 3, according to one or more embodiments of the present disclosure;

FIG. 5 is a layout diagram illustrating the part D of FIG. 3, according to one or more embodiments of the present disclosure;

FIG. 6 is an equivalent circuit diagram showing a light emitting pixel driver of FIG. 5, according to one or more embodiments of the present disclosure;

FIG. 7 is a cross-sectional view taken along the line E-E′ of FIG. 5, according to one or more embodiments of the present disclosure;

FIG. 8 is an enlarged perspective view showing the part C of FIG. 1, according to one or more embodiments of the present disclosure;

FIG. 9 is a flowchart illustrating a method for manufacturing the display device according to one or more embodiments of the present disclosure;

FIG. 10 is a cross-sectional view illustrating a mold member and a process diagram of the step (e.g., act or task) of attaching the display panel onto the guide member of FIG. 9, according to one or more embodiments of the present disclosure;

FIGS. 11, 12, and 13 are each a plan view showing the guide member of FIG. 10 according to one or more embodiments of the present disclosure;

FIG. 14 is a cross-sectional view taken along the line F-F′ of FIG. 11, according to one or more embodiments of the present disclosure;

FIG. 15 is a process diagram illustrating the step (e.g., act or task) of attaching the display panel onto the guide member of FIG. 9, according to one or more embodiments of the present disclosure;

FIGS. 16, 17, 18, 19, and 20 are process diagrams illustrating some of the steps of FIG. 9, according to one or more embodiments of the present disclosure;

FIGS. 21, 22, 23, and 24 are process diagrams illustrating the step (e.g., act or task) of transforming the guide member of FIG. 9, according to one or more embodiments of the present disclosure;

FIG. 25 is a cross-sectional view taken along the line F-F′ of FIG. 11, according to one or more embodiments of the present disclosure;

FIGS. 26, 27, 28, and 29 are process diagrams illustrating some of the steps of FIG. 9 according to one or more embodiments of the present disclosure;

FIG. 30 is a plan view showing a guide member according to one or more embodiments of the present disclosure;

FIG. 31 is a cross-sectional view taken along the line I-I′ of FIG. 30, according to one or more embodiments of the present disclosure; and

FIGS. 32, 33, 34, and 35 are process diagrams illustrating some of the steps of FIG. 9 according to one or more embodiments of FIGS. 30 and 31, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

Unless otherwise noted, like reference numerals denote like elements throughout the attached drawings and the written description, and thus, duplicative descriptions thereof may not be provided. In the drawings, the relative sizes of elements, layers, and regions may be exaggerated for clarity.

Some of the parts which are not associated with the description may not be provided in order to describe embodiments of the disclosure.

It will be understood that when an element, such as an area, layer, film, region, substrate or portion, is referred to as being “on” or “connected to” another element, it can be directly on or connected to the other element, or one or more intervening elements may be present. In contrast, when an element or layer is referred to as being “directly on,” “directly connected to”, or “immediately adjacent to” another element or layer, there are no intervening elements or layers present. In addition, it will also be understood that when an element is referred to as being “between” two elements, it can be the only element between the two elements, or one or more intervening elements may also be present. In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the direction DR3 refers to a top-down view of the display panel, as if looking directly down onto the surface from above. In this context, DR3 is the direction perpendicular or normal to the plane defined by the first direction (DR1) and the second direction (DR2). This refers to that in a plan view, the arrangement of sub-pixels, pads, and other components as they are laid out on the substrate can be seen, without any perspective distortion. The phrase “in a schematic cross-sectional view” refers to when a schematic cross-section taken by vertically cutting an object portion is viewed from the side.

The terms “overlap” or “overlapped” refer to that a first object may be above or below or to a side of a second object, and vice versa. Additionally, the term “overlap” may include layer, stack, face or facing, extending over, covering, or partly covering and/or any other suitable term as would be appreciated and understood by those of ordinary skill in the art. The expression “not overlap” may refer to being “apart from,” “set aside from,” “offset from” and/or any other suitable equivalents as would be appreciated and understood by those of ordinary skill in the art. The terms “face” and “facing” may refer to that a first object may directly or indirectly oppose a second object. In a case in which a third object intervenes between a first and second object, the first and second objects may be understood as being indirectly opposed to one another, although still facing each other.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

When an element is referred to as being “connected” or “coupled” to another element, the element may be “directly connected” or “directly coupled” to another element, or “electrically connected” or “electrically coupled” to another element with one or more intervening elements interposed therebetween.

. It will be further understood that the terms “comprises,” “comprising,” “includes,” “including,” “have,” “having,” “contain,” and “containing,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having”, or the like include or support the terms “consisting of” and “consisting essentially of,” indicating the presence of stated features, integers, steps, operations, elements, and/or components, with or without the presence of other features, integers, steps, operations, elements, components, and/or groups thereof.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the term “substantially,” “about,” and similar terms are used as terms of approximation and not as terms of degree, and are intended to account for the inherent deviations in measured or calculated values that would be recognized by those of ordinary skill in the art. “Substantially” or “about” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” or “about” may mean within one or more standard deviations, or within ±30%, 20%, 10%, 5% of the stated value.

As used herein, the term “and/or” includes any and all combinations of one or more of the associated listed items. For example, “A and/or B” may be understood to refer to “A, B, or A and B.” The terms “and” and “or” may be used in the conjunctive or disjunctive sense and may be understood to be equivalent to “and/or.” Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof. In the specification and the claims, the phrase “at least one of” is intended to include the meaning of “at least one selected from among the group of” for the purpose of its meaning and interpretation.

As used herein, the terms “use,” “using,” and “used” may be considered synonymous with the terms “utilize,” “utilizing,” and “utilized,” respectively.

As used herein, the singular forms “a,” “an” and “the” are intended to include the plural forms as well, unless the context clearly indicates otherwise.

Further, the use of “may” when describing embodiments of the present disclosure refers to “one or more embodiments of the present disclosure.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and/or specification, and should not be interpreted in an idealized or overly formal sense, unless expressly so defined herein.

Hereinafter, embodiments will be described with reference to the accompanying drawings.

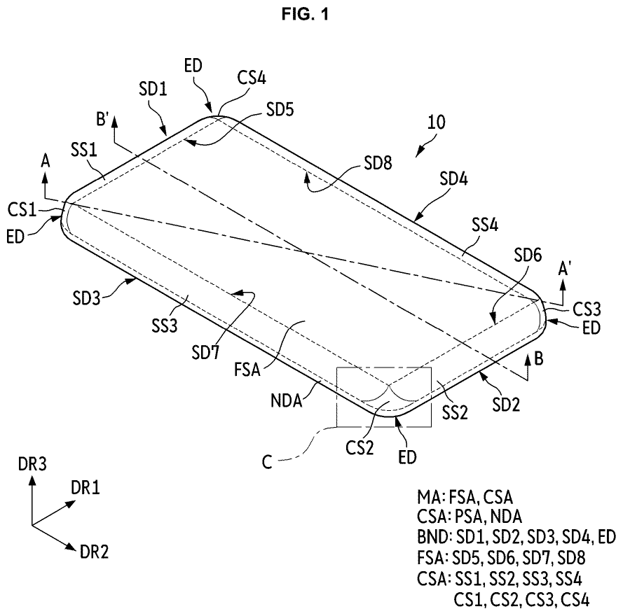

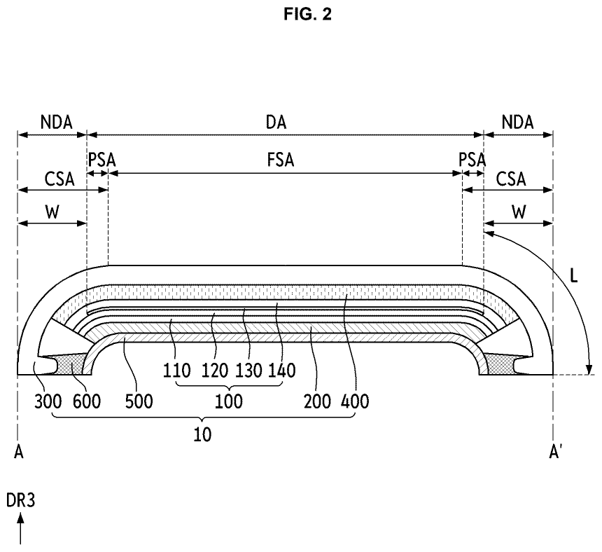

FIG. 1 is a perspective view illustrating a display device according to one or more embodiments of the present disclosure. FIG. 2 is a cross-sectional view taken along the line A-A′ of FIG. 1, according to one or more embodiments of the present disclosure.

Referring to FIG. 1, a display device 10 according to one or more embodiments, which is a device for displaying a moving image and/or a still image, may be used as a display screen of one or more suitable devices, such as a television, a laptop computer, a monitor, a billboard and/or an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and/or an ultra-mobile PC (UMPC).

In one or more embodiments, the display device 10 according to one or more embodiments may be applied to a car display, such as the dashboard of a vehicle, a center fascia of a vehicle, a center information display (CID) arranged on a dashboard of a vehicle, a room mirror display in place of side mirrors of a vehicle, or a display arranged on a rear surface of a front seat of a vehicle for rear seat entertainment.

Referring to FIG. 2, the display device 10 according to one or more embodiments may include a display panel 100 to emit light for image display, a cover window 300 arranged on the display panel 100, and a transparent adhesive layer 400 arranged between the display panel 100 and the cover window 300.

The display device 10 according to one or more embodiments may further include a metal plate 200 arranged below the display panel 100 and supporting the display panel 100, a bracket 500 arranged below the metal plate 200 and supporting the display panel 100 and the metal plate 200, and a sealing layer 600 that fixes the cover window 300 to the bracket 500.

The display panel 100 may be a light emitting display panel including a light emitting element. For example, the display panel 100 may be an organic light emitting display panel using an organic light emitting diode including an organic light emitting layer, a micro light emitting diode display panel using a micro LED, a quantum dot light emitting display panel using a quantum dot light emitting diode including a quantum dot light emitting layer, or an inorganic light emitting display panel using an inorganic light emitting element including an inorganic semiconductor. The following description is directed to the case where the display panel 100 is an organic light emitting display panel, but the present disclosure is not limited thereto.

According to one or more embodiments, the display panel 100 may include a substrate 110, a circuit layer 120 arranged on the substrate 110, and an element layer 130 arranged on the circuit layer 120.

The display panel 100 may further include an encapsulation layer 140 arranged on the element layer 130.

The substrate 110 may include a flat display area FSA having a planar shape, and a curved area CSA arranged around the flat display area and having a curved shape.

The curved area PSA may include a peripheral display area PSA arranged around the flat display area FSA, and a non-display area NDA arranged around the peripheral display area PSA.

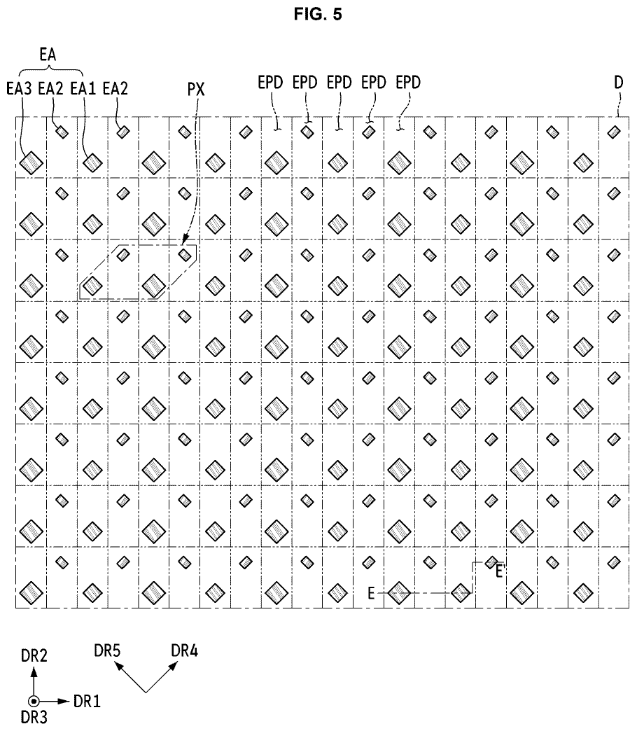

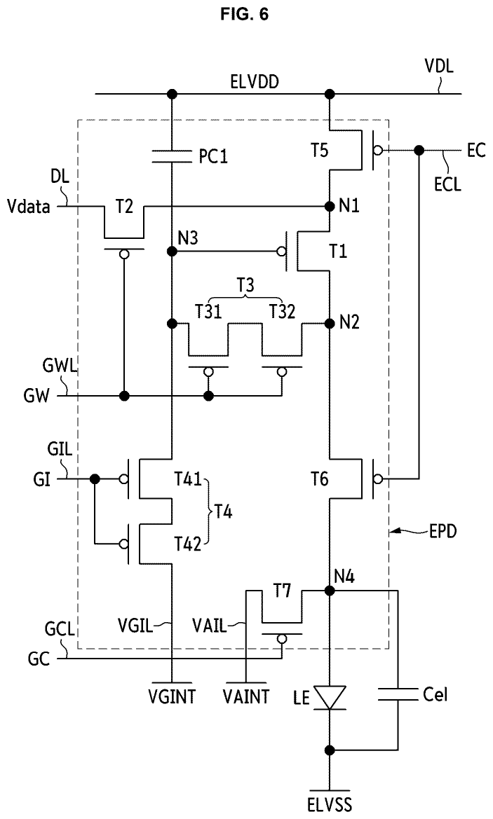

The element layer 130 may include light emitting elements LE (see, e.g., FIG. 6) arranged in emission areas EA (see, e.g., FIG. 5).

The circuit layer 120 may include light emitting pixel drivers EPD (see, e.g., FIG. 5) that transmit a driving current to the light emitting elements LE.

The encapsulation layer 140 is arranged on the element layer 130 and may have a structure in which two or more inorganic films and at least one organic film are alternately stacked.

The metal plate 200 is intended to prevent or reduce deformation of the display panel 100 prior to being fastened to the bracket 500.

The cover window 300 may contain a light-transmissive rigid material. The cover window 300 may be made of an inorganic material such as glass, or an organic material such as plastic or a polymer material.

The cover window 300 may be attached onto the display panel 100 through the transparent adhesive layer 400.

The transparent adhesive layer 400 may be an optically clear adhesive (OCA) film or an optically clear resin (OCR).

Because of the cover window 300, the display panel 100 may be protected from electrical and physical impacts on the display surface or defects caused by such impacts may be reduced.

The bracket 500 may include a rigid insulating material to prevent or reduce deformation of the display panel 100 and to mitigate external physical and electrical impacts on the display panel 100. However, this is merely an example, and the material of the bracket 500 may be variously changed.

As shown in FIG. 1, according to one or more embodiments, a (e.g., one) surface of the display device 10 on which an image is displayed may include a main region MA.

For example, the main region MA may have a quadrilateral shape.

In such embodiments, an edge BND of the main region MA may include a first side SD1 and a second side SD2 extending in the first direction DR1, the first and second sides SD1 and SD2 opposing each other in the second direction DR2, a third side SD3 and a fourth side SD4 extending in the second direction DR2, the third and the fourth sides SD3 and SD4 opposing each other in the first direction DR1, and corners ED connecting two sides. In other words, the corners ED may be at each intersection between the first, second, third, and fourth sides SD1, SD2, SD3, and SD4, and connecting the sides at each intersection. For example, one corner ED may connect an end of the first side SD1 to an end of the fourth side SD4, one corner ED may connect another end of the fourth side SD4 to an end of the second side SD2, one corner ED may connect another end of the second side SD2 to an end of the third side SD3, and one corner ED may connect another end of the third side SD3 to another end of the first side SD1.

Each of the corners ED may connect one of the first and/or second sides SD1 and SD2 to one of the third and/or fourth sides SD3 and SD4.

The first side SD1 and the second side SD2 may have a shorter length than the third side SD3 and the fourth side SD4.

According to one or more embodiments, the main region MA may include the flat display area FSA having a planar shape, and the curved area CSA arranged around the flat display area FSA and having a curved shape.

The curved area CSA may include the peripheral display area PSA arranged around the flat display area FSA, and the non-display area NDA arranged between the peripheral display area PSA and the edge BND of the main region MA.

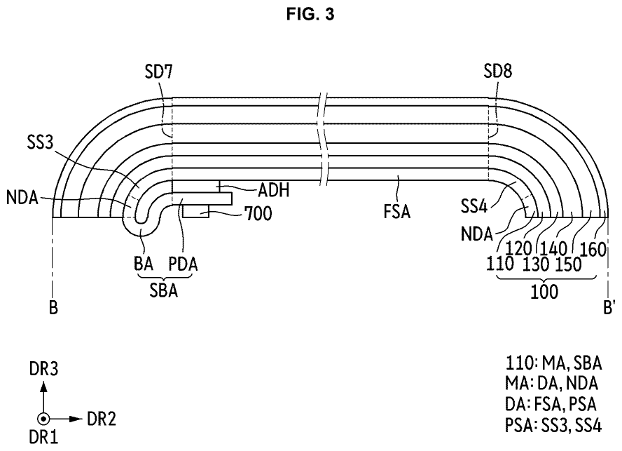

In the flat display area FSA and the peripheral display area PSA, the emission areas EA (see, e.g., FIG. 5) from which light is emitted may be arranged. Accordingly, the flat display area FSA and the peripheral display area PSA may be collectively referred to as a display area DA (see, e.g., FIGS. 2 and 3).

The flat display area FSA may include a fifth side SD5 and a sixth side SD6 extending in the first direction DR1 and opposing each other in the second direction DR2, and a seventh side SD7 and an eighth side SD8 extending in the second direction DR2 and opposing each other in the first direction DR1.

For example, the flat display area FSA may have a shape similar to the main region MA. For example, if (e.g., when) the main region MA has a quadrilateral shape, the fifth side SD5 and the sixth side SD6 may have a shorter length than the seventh side SD7 and the eighth side SD8.

In one or more embodiments, the connection points where one of the fifth and sixth sides SD5 and SD6 meets one of the seventh and eighth sides SD7 and SD8 may be formed as a curved arc or a right-angled vertex.

However, the shape of the flat display area FSA is not limited to the quadrangle shown in FIG. 1 and may be a circle, an ellipse, or a polygon other than the quadrangle.

The curved area CSA may include side areas in contact with the sides of the flat display area FSA and corner areas in contact with the vertices of the flat display area FSA.

The side areas of the curved area CSA may include a first side area SS1 between the first side SD1 and the fifth side SD5, a second side area SS2 between the second side SD2 and the sixth side SD6, a third side area SS3 between the third side SD3 and the seventh side SD7, and a fourth side area SS4 between the fourth side SD4 and the eighth side SD8.

The corner areas oof the curved area CSA may include a first corner area CS1 in contact with a vertex between the fifth side SD5 and the seventh side SD7 and arranged between the first side area SS1 and the third side area SS3, a second corner area CS2 in contact with a vertex between the sixth side SD6 and the seventh side SD7 and arranged between the second side area SS2 and the third side area SS3, a third corner area CS3 in contact with a vertex between the sixth side SD6 and the eighth side SD8 and arranged between the second side area SS2 and the fourth side area SS4, and a fourth corner area CS4 in contact with a vertex between the fifth side SD5 and the eighth side SD8 and arranged between the first side area SS1 and the fourth side area SS4.

Each of the first side area SS1, the second side area SS2, the third side area SS3, the fourth side area SS4, a first corner area CS1, a second corner area CS2, a third corner area CS3, and a fourth corner area CS4 may include the peripheral display area PSA and the non-display area NDA.

The first side area SS1 may extend from the fifth side SD5 and be curved with a first curvature in a direction opposite to the direction in which light is emitted (e.g., the first curvature may be convex relative to the exterior surface of the display device 10).

The second side area SS2 may extend from the sixth side SD6 and be curved with a second curvature in a direction opposite to the direction in which light is emitted (e.g., the second curvature may be convex relative to the exterior surface of the display device 10). The second curvature may be in substantially the same range as (e.g., the amount of curvature may be substantially the same as) the first curvature.

The third side area SS3 may extend from the seventh side SD7 and be curved with a third curvature in a direction opposite to the direction in which light is emitted (e.g., the third curvature may be convex relative to the exterior surface of the display device 10). The third curvature may be in substantially the same or may have a similar range as (e.g., the amount of curvature may be substantially the same as or similar to) the first curvature or the second curvature, but the present disclosure is not limited thereto.

The fourth side area SS4 may extend from the eighth side SD8 and be curved with a fourth curvature in a direction opposite to the direction in which light is emitted (e.g., the fourth curvature may be convex relative to the exterior surface of the display device 10). The fourth curvature may be in substantially the same range as (e.g., the amount of curvature may be substantially the same as) the third curvature.

The first corner area CS1 may be arranged between one side (end) of the first side area SS1 and one side (end) of the third side area SS3.

The first corner area CS1 may be a double curvature region that is curved with the first curvature of the first side area SS1 and the third curvature of the third side area SS3.

The second corner area CS2 may be arranged between one side (end) of the second side area SS2 and the other side (end) of the third side area SS3.

The second corner area CS2 may be a double curvature region that is curved with the second curvature of the second side area SS2 and the third curvature of the third side area SS3.

The third corner area CS3 may be arranged between the other side (end) of the second side area SS2 and one side (end) of the fourth side area SS4.

The third corner area CS3 may be a double curvature region that is curved with the second curvature of the second side area SS2 and the fourth curvature of the fourth side area SS4.

The fourth corner area CS4 may be arranged between the other side (end) of the first side area SS1 and the other side (end) of the fourth side area SS4.

The fourth corner area CS4 may be a double curvature region that is curved with the first curvature of the first side area SS1 and the fourth curvature of the fourth side area SS4.

As shown in FIG. 2, the display device 10 may include the flat display area FSA having a planar shape and the curved area CSA having a curved shape.

In the peripheral display area PSA of the curved area CSA arranged around the flat display area FSA, light may be emitted as in the flat display area FSA.

For example, according to one or more embodiments, the display area DA, from which light is to be emitted, of the main region MA of the display device 10, may further include the peripheral display area PSA having a curved shape, as well as the flat display area FSA having a planar shape.

Additionally, the curved area CSA of a curved shape may include the non-display area NDA from which light is not emitted. Accordingly, in a front direction (e.g., in a direction opposite to the third direction DR3) facing the display device 10, a width W of the non-display area NDA in a curved form may be smaller than a width L of the non-display area NDA in a flat form.

Therefore, as the width W of the non-display area NDA visually recognizable from the front direction is reduced, the proportion of the display area DA in the main region MA may be increased, thereby improving the aesthetics and compatibility of the display device 10.

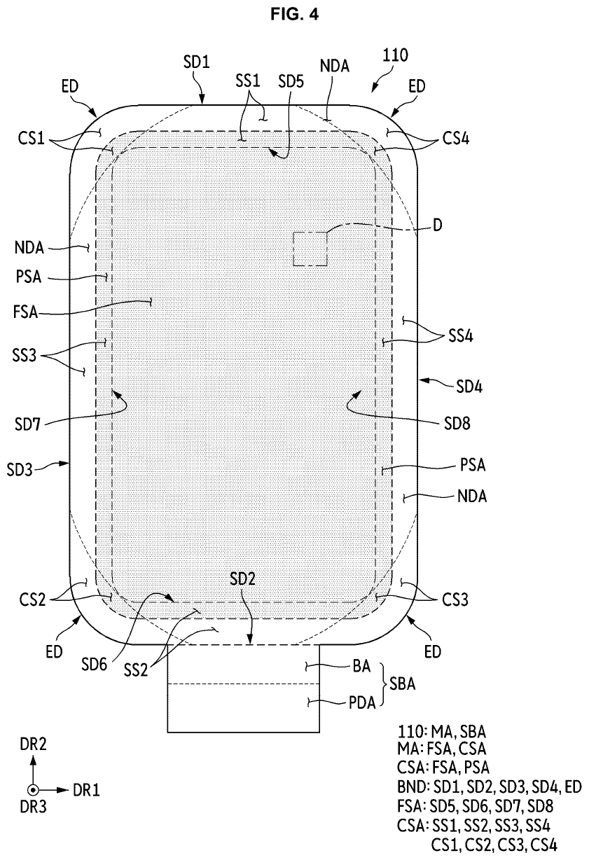

FIG. 3 is a cross-sectional view showing the display panel taken along the line B-B′ of FIG. 1, according to one or more embodiments of the present disclosure. FIG. 4 is a plan view showing the substrate of FIG. 3, according to one or more embodiments of the present disclosure. FIG. 5 is a layout diagram illustrating the part D of FIG. 3, according to one or more embodiments of the present disclosure.

Referring to FIG. 3, the display panel 100 of the display device 10 according to one or more embodiments may include the substrate 110, the circuit layer 120 arranged on the substrate 110, and the element layer 130 arranged on the circuit layer 120.

The substrate 110 may include the main region MA and a sub-region SBA.

The main region MA may include the display area DA and the non-display area NDA arranged around the display area DA.

The display area DA may include the flat display area FSA, and the peripheral display area PSA arranged around the flat display area FSA and having a curved shape.

The edge of the flat display area FSA may include the fifth side SD5 and the sixth side SD6 opposite to each other in the second direction DR2.

The peripheral display area PSA may be arranged in each of the first side area SS1 in contact with the fifth side SD5 of the flat display area FSA, and the second side area SS2 in contact with the sixth side SD6 of the flat display area FSA.

As shown in FIG. 4, the edge of the flat display area FSA may further include the seventh side SD7 and the eighth side SD8 opposing each other in the first direction DR1.

The peripheral display area PSA may be further arranged in each of the third side area SS3 in contact with the seventh side SD7 of the flat display area FSA, and the fourth side area SS4 in contact with the eighth side SD8 of the flat display area FSA.

As shown in FIG. 5, in the display area DA including the flat display area FSA and the peripheral display area PSA, the emission areas EA may be arranged side by side with each other.

The display area DA may further include a non-emission area arranged in a gap between the emission areas EA.

The emission areas EA may each have a rhombic shape or a rectangular shape in a plan view. However, this is only an example, and the planar shape of the emission areas EA is not limited to that illustrated in FIG. 5. For example, in a plan view, the emission areas EA may have a polygonal shape such as a quadrangle, a pentagon, and/or a hexagon, or may have a circular or elliptical shape including the edge of a curve.

The emission areas EA may include first emission areas EA1 that emit light in a first wavelength band, second emission areas EA2 that emits light in a second wavelength band lower than the first wavelength band, and third emission areas EA3 that emits light in a third wavelength band lower than the second wavelength band.

For example, the first wavelength band may be from about 600 nm to about 750 nm and may be visually recognized as red. The second wavelength band may be from about 480 nm to about 560 nm and may be visually recognized as green. The third wavelength band may be from about 370 nm to about 460 nm and may be visually recognized as blue.

The first emission areas EA1 and the third emission areas EA3 may be alternately arranged in at least one of the first direction DR1 or the second direction DR2.

The second emission areas EA2 may be arranged side by side in at least one of the first direction DR1 or the second direction DR2.

In addition, the second emission areas EA2 may be adjacent to the first emission areas EA1 and the third emission areas EA3 in diagonal directions DR4 and DR5 crossing the first direction DR1 and the second direction DR2.

Pixels PX displaying their own luminances and colors may be provided by the first emission area EA1, the second emission area EA2, and the third emission area EA3 adjacent to each other among these emission areas EA.

For example, the pixel PX may be a basic unit for displaying one or more suitable colors including white with a set or predetermined luminance.

Each of the pixels PX may include at least one first emission area EA1, at least one second emission area EA2, and at least one third emission area EA3 that are adjacent to each other. Accordingly, each of the pixels PX may display one or more suitable colors through a mixture of the light emitted from the first emission area EA1, the second emission area EA2, and the third emission area EA3 that are adjacent to each other.

As shown in FIG. 4, the sub-region SBA may protrude from at least a portion of the second side SD2 of the main region MA.

The sub-region SBA may include a bending area BA, which is transformed into a bent shape (e.g., which is bent), and a pad area PDA, which is connected to the bending area BA.

As shown in FIG. 3, if (e.g., when) the bending area BA is transformed into a bent shape, the pad area PDA may be arranged on the rear surface of the substrate 110 of the display panel 100.

The pad area PDA may be fixed to the rear surface of the display panel 100 through a pad auxiliary adhesive layer ADH (see, e.g., FIG. 3).

According to one or more embodiments, the display panel 100 may further include the encapsulation layer 140 arranged on the element layer 130, a touch sensor layer 150 arranged on the encapsulation layer 140, and a polarization layer 160 arranged on the touch sensor layer 150, as shown, for example, in FIG. 3.

The encapsulation layer 140 is arranged on the element layer 130 and may have a structure in which two or more inorganic films and at least one organic film are alternately stacked.

The touch sensor layer 150 may include touch electrodes for detecting a signal that varies depending on the touch of a person or an object and sensing a point in the main region MA in which the touch of the person or the object has occurred.

The polarization layer 160 blocks external light reflected from the touch sensor layer 150, the encapsulation layer 140, the element layer 130, and the circuit layer 120, and the interfaces thereof, to prevent or reduce the deterioration of visibility of an image due to external light reflection.

FIG. 6 is an equivalent circuit diagram showing a light emitting pixel driver of FIG. 5, according to one or more embodiments of the present disclosure. In one or more embodiments, each pixel PX may include a light emitting pixel driver EPD and while FIG. 6 shows a single light emitting pixel driver EPD, the remaining pixels PX of the display device 10 may have the same or a substantially similar light emitting pixel driver EPD as described with reference to FIG. 6.

Referring to FIG. 6, the circuit layer 120 (see, e.g., FIG. 3) according to one or more embodiments may include a first power line VDL for transmitting a first power source ELVDD to the light emitting pixel drivers EPD, a second power line for transmitting a second power source ELVSS to the light emitting elements LE, a gate initialization voltage line VGIL for transmitting a gate initialization voltage VGINT to the light emitting pixel drivers EPD, and an anode initialization voltage line VAIL for transmitting an anode initialization voltage VAINT.

The light emitting elements LE of the element layer 130 (see, e.g., FIG. 3) may be electrically connected between the light emitting pixel drivers EPD and the second power source ELVSS.

For example, one of the light emitting elements LE may be electrically connected between one of the light emitting pixel drivers EPD of the circuit layer 120 and the second power source ELVSS.

The second power source ELVSS may be at a voltage level lower than that of the first power source ELVDD.

For example, the anode electrode of the light emitting element LE is electrically connected to the light emitting pixel driver EPD, and the second power source ELVSS may be applied to the cathode electrode of the light emitting element LE, where the second power source ELVSS has a voltage level lower than the first power source ELVDD.

A capacitor Cel connected in parallel with the light emitting element LE refers to a parasitic capacitance between the anode electrode and the cathode electrode.

The circuit layer 120 may further include a data line DL that transmits a data signal Vdata, a scan write line GWL that transmits a scan write signal GW, a scan initialization line GIL that transmits a scan initialization signal GI, a gate control line GCL that transmits a gate control signal GC, and an emission control line ECL that transmits an emission control signal EC.

One light emitting pixel driver EPD of the circuit layer 120 may include a first transistor T1 configured to generate a driving current for driving the light emitting element LE, two or more transistors T2 to T6 electrically connected to the first transistor T1, and at least one capacitor PC1.

The first transistor T1 may be electrically connected between a first node N1 and a second node N2. The first node N1 is electrically connected to the first electrode (e.g., source electrode) of the first transistor T1. The second node N2 is electrically connected to the second electrode (e.g., drain electrode) of the first transistor T1.

The second transistor T2 may be electrically connected between the data line DL and the first node N1.

The second transistor T2 may be turned on by the scan write signal GW of the scan write line GWL.

The first electrode of the first transistor T1 may be electrically connected to the data line DL through the turned-on second transistor T2.

The first capacitor PC1 may be electrically connected between the first power line VDL and a third node N3. The third node N3 is electrically connected to the gate electrode of the first transistor T1.

For example, the gate electrode of the first transistor T1 may be electrically connected to the first power line VDL through the first capacitor PC1.

The fifth transistor T5 may be electrically connected between the first node N1 and the first power line VDL.

The sixth transistor T6 may be electrically connected between the second node N2 and a fourth node N4. The fourth node N4 is electrically connected to the anode electrode of the light emitting element LE.

For example, the fifth transistor T5 may be electrically connected between the first electrode of the first transistor T1 and the first power line VDL.

The sixth transistor T6 may be electrically connected between the second electrode of the first transistor T1 and the anode electrode of the light emitting element LE.

The fifth transistor T5 and the sixth transistor T6 may be turned on by the emission control signal EC of the emission control line ECL.

When the data signal Vdata of the data line DL is transmitted to the first electrode of the first transistor T1 through the turned-on second transistor T2, the voltage difference between the gate electrode of the first transistor T1 and the first electrode of the first transistor T1 may correspond to a difference voltage between the first power source ELVDD and the data signal Vdata.

In such embodiments, if (e.g., when) the voltage difference between the gate electrode of the first transistor T1 and the first electrode of the first transistor T1, i.e., the gate-source voltage difference, becomes equal to or greater than a threshold voltage, the first transistor T1 may be turned on, thereby generating a drain-source current of the first transistor T1 corresponding to the data signal Vdata.

Subsequently, if (e.g., when) the fifth transistor T5 and the sixth transistor T6 are turned on, the first power source ELVDD, the first transistor T1, the light emitting element LE, and the second power source ELVSS may be connected in series. Accordingly, the drain-source current of the first transistor T1 corresponding to the data signal Vdata may be supplied as a driving current of the light emitting element LE.

Accordingly, the light emitting element LE may be to emit light having a luminance corresponding to the data signal Vdata.

The third transistor T3 may be electrically connected between the second node N2 and the third node N3. For example, the third transistor T3 may be electrically connected between the gate electrode of the first transistor T1 and the second electrode of the first transistor T1.

The third transistor T3 may include a plurality of sub-transistors connected in series. For example, the third transistor T3 may include a first sub-transistor T31 and a second sub-transistor T32.

The first electrode of the first sub-transistor T31 may be connected to the gate electrode of the first transistor T1, the second electrode of the first sub-transistor T31 may be connected to the first electrode of the second sub-transistor T32, and the second electrode of the second sub-transistor T32 may be connected to the second electrode of the first transistor T1.

In this way, it is possible to prevent or reduce the likelihood of the potential of the gate electrode of the first transistor T1 from changing due to the leakage current generated by the third transistor T3 that is not turned on. For example, when the third transistor T3 is not turned on, it may still allow a small amount of current, known as leakage current, to flow through it. This leakage current may inadvertently alter the voltage (potential) at the gate electrode of the first transistor T1. If the gate voltage changes unexpectedly, it can affect the operation of the first transistor T1, potentially leading to incorrect functioning of the circuit. By using a configuration with sub-transistors in series, the design helps to minimize this leakage current, thereby maintaining the desired gate voltage and ensuring stable operation of the first transistor T1.

The first sub-transistor T31 and the second sub-transistor T32 may be turned on by the scan write signal GW of the scan write line GWL.

When the first sub-transistor T31 and the second sub-transistor T32 are turned on, the voltage difference between the second node N2 and the third node N3 may be initialized.

The fourth transistor T4 may be electrically connected between the gate initialization voltage line VGIL and the third node N3. For example, the fourth transistor T4 may be connected between the gate electrode of the first transistor T1 and the gate initialization voltage line VGIL.

The fourth transistor T4 may include a plurality of sub-transistors connected in series. For example, the fourth transistor T4 may include a third sub-transistor T41 and a fourth sub-transistor T42.

The first electrode of the third sub-transistor T41 may be connected to the gate electrode of the first transistor T1, the second electrode of the third sub-transistor T41 may be connected to the first electrode of the fourth sub-transistor T42, and the second electrode of the fourth sub-transistor T42 may be connected to the gate initialization voltage line VGIL.

In this way, it is possible to prevent or reduce the likelihood of the potential of the gate electrode of the first transistor T1 from changing due to the leakage current caused by the fourth transistor T4 that is not turned on.

The third sub-transistor T41 and the fourth sub-transistor T42 may be turned on by the scan initialization signal GI of the scan initialization line GIL.

When the third sub-transistor T41 and the fourth sub-transistor T42 are turned on, the potential of the third node N3 may be initialized to the gate initialization voltage VGINT.

The seventh transistor T7 may be electrically connected between the fourth node N4 and the anode initialization voltage line VAIL. For example, the seventh transistor T7 may be electrically connected between the anode electrode of the light emitting element LE and the anode initialization voltage line VAIL.

The seventh transistor T7 may be turned on by the gate control signal GC of the gate control line GCL.

Through the turned-on seventh transistor T7, the potential of the fourth node N4 may be initialized to the anode initialization voltage VAINT.

In one or more embodiments, FIG. 6 illustrates the light emitting pixel driver EPD including the first to seventh transistors T1 to T7 formed as P-type (kind) MOSFETs. However, this is merely an example, and at least one of the first to seventh transistors T1 to T7 may be an N-type (kind) MOSFET. For example, the third transistor T3 and the fourth transistor T4 may be N-type (kind) MOSFETs.

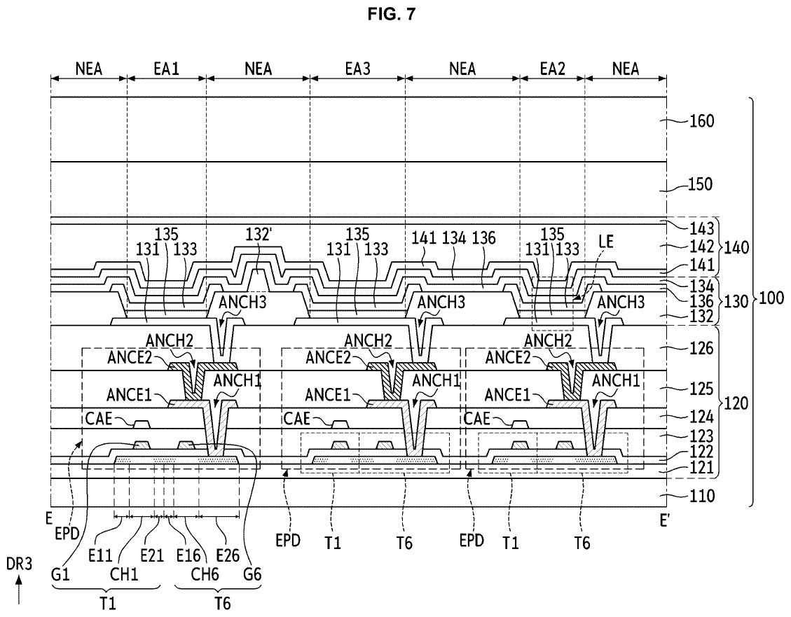

FIG. 7 is a cross-sectional view taken along the line E-E′ of FIG. 5, according to one or more embodiments of the present disclosure.

Referring to FIG. 7, the display panel 100 of the display device 10 according to one or more embodiments may include the substrate 110, the circuit layer 120 on the substrate 110, and the element layer 130 on the circuit layer 120.

The display panel 100 of the display device 10 according to one or more embodiments may further include the encapsulation layer 140 on the element layer 130, the touch sensor layer 150 on the encapsulation layer 140, and the polarization layer 160 on the touch sensor layer 150.

The circuit layer 120 may include a first semiconductor layer (in FIG. 7, the first semiconductor layer includes channel portions CH1 and CH6, first electrode portions E11 and E16, and second electrode portions E21 and E26 of the first transistor T1 and the sixth transistor T6) arranged on the substrate 110, a first gate insulating layer 122 covering the first semiconductor layer, a first gate conductive layer (in FIG. 7, the first gate conductive layer includes gate electrodes G1 and G6 of the first transistor T1 and the sixth transistor T6) arranged on the first gate insulating layer 122, a second gate insulating layer 123 covering the first gate conductive layer, a second gate conductive layer (in FIG. 7, the second gate conductive layer includes capacitor electrodes CAE) arranged on the second gate insulating layer 123, an interlayer insulating layer 124 arranged on the second gate conductive layer, a first source-drain conductive layer (in FIG. 7, the first source-drain conductive layer includes first anode connection electrodes ANCE1) arranged on the interlayer insulating layer 124, a first planarization layer 125 covering the first source-drain conductive layer, a second source-drain conductive layer (in FIG. 7, the second source-drain conductive layer includes second anode connection electrodes ANCE2) arranged on the first planarization layer 125, and a second planarization layer 126 covering the second source-drain conductive layer.

The circuit layer 120 may further include a buffer layer 121 covering the substrate 110.

In such embodiments, the first semiconductor layer CH1, E11, E21, CH6, E16, and E26 may be arranged on the buffer layer 121.

The circuit layer 120 may include the light emitting pixel drivers EPD respectively corresponding to the emission areas EA.

According to one or more embodiments of FIG. 6, each of the light emitting pixel drivers EPD may include the first transistor T1, and the first capacitor PC1 (see, e.g., FIG. 6) and the second to seventh transistors T2 to T7 (see, e.g., FIG. 6) electrically connected to the first transistor T1.

FIG. 7 shows the first transistor T1, the sixth transistor T6, and the light emitting element LE of the light emitting pixel driver EPD of FIG. 6.

As illustrated in FIG. 7, the channel portions CH1 and CH6, the first electrode portions E11 and E16, and the second electrode portions E21 and E26 of the first transistor T1 and the sixth transistor T6 may be arranged in the first semiconductor layer on the buffer layer 121.

In the first transistor T1 and the sixth transistor T6, each of the first electrode portions E11 and E16 may be connected to one end of one of the channel portions CH1 and CH6, respectively, and each of the second electrode portions E21 and E26 may be connected to another end of one of the channel portions CH1 and CH6, respectively. In other words, the first electrode portion E11 may be connected to one end of the channel portion CH1 and the second electrode portion E21 may be connected to the other end of the channel portion CH1. In addition, the first electrode portion E16 may be connected to one end of the channel portion CH6 and the second electrode portion E26 may be connected to the other end of the channel portion CH6.

The second electrode portion E21 of the first transistor T1 may be connected to the first electrode portion E16 of the sixth transistor T6.

The first gate conductive layer on the first gate insulating layer 122 may include the gate electrodes G1 and G6 of the first transistor T1 and the sixth transistor T6, respectively.

In the first transistor T1 and the sixth transistor T6, the gate electrodes G1 and G6 may overlap the channel portions CH1 and CH6, respectively.

In the light emitting pixel driver EPD of FIG. 6, the second transistor T2, the first sub-transistor T31, the second sub-transistor T32, the third sub-transistor T41, the fourth sub-transistor T42, the fifth transistor T5, and the seventh transistor T7 may each independently be the same P-type (kind) MOSFETs as the first and sixth transistors T1 and T6, and therefore duplicate descriptions thereof may not be provided.

The second gate conductive layer on the second gate insulating layer 123 may include the capacitor electrode CAE.

The capacitor electrode CAE may overlap the gate electrode G1 of the first transistor T1.

Accordingly, the first capacitor PC1 (see, e.g., FIG. 6) may be provided by the overlapping area between the capacitor electrode CAE and the gate electrode G1 of the first transistor T1.

The first source-drain conductive layer on the interlayer insulating layer 124 may include first anode connection electrodes ANCE1.

The first anode connection electrodes ANCE1 may be electrically connected to the second electrode portions E26 of the sixth transistor T6 through first anode connection holes ANCH1.

The second source-drain conductive layer on the first planarization layer 125 may include second anode connection electrodes ANCE2.

The second anode connection electrodes ANCE2 may be electrically connected to the first anode connection electrodes ANCE1 through second anode connection holes ANCH2.

The element layer 130 on the circuit layer 120 may include the light emitting elements LE respectively arranged in the emission areas EA1, EA2, and EA3.

Each of the light emitting elements LE may include a structure in which a light emitting layer 133 is arranged between the anode electrode 131 and a cathode electrode 134, where the anode electrode 131 and the cathode electrode 134 are opposite to (e.g., face) each other.

The anode electrode 131 may be arranged on the second planarization layer 126, and may be electrically connected to the second anode connection electrode ANCE2 through a third anode connection hole ANCH3.

Accordingly, the anode electrode 131 may be electrically connected to the second electrode portion E26 of the sixth transistor T6 through the first anode connection electrode ANCE1 and the second anode connection electrode ANCE2.

In accordance with one or more embodiments, the element layer 130 may include the anode electrodes 131 respectively arranged in the emission areas EA, a pixel defining layer 132 arranged in the non-emission area NEA and covering the edges of the anode electrodes 131, a spacer layer 132′ arranged on a part of the pixel defining layer 132, the light emitting layers 133 respectively arranged on the anode electrodes 131, and the cathode electrode 134 arranged on the light emitting layers 133, the pixel defining layer 132, and the spacer layer 132′.

In one or more embodiments, each of the light emitting elements LE may further include first common layers 135 arranged between the anode electrodes 131 and the light emitting layers 133, and a second common layer 136 arranged between the light emitting layers 133 and the cathode electrode 134.

The encapsulation layer 140 may be arranged on the circuit layer 120 and cover the element layer 130.

The encapsulation layer 140 is to block, reduce and/or protect the element layer 130 from the permeation of oxygen or moisture into the element layer 130 and to reduce electrical or physical impact to the circuit layer 120 and the element layer 130.

The encapsulation layer 140 may include a first encapsulation layer 141 arranged on the circuit layer 120, covering the element layer 130, and including an inorganic insulating material, a second encapsulation layer 142 arranged on the first encapsulation layer 141, overlapping the element layer 130, and including an organic insulating material, and a third encapsulation layer 143 arranged on the first encapsulation layer 141, covering the second encapsulation layer 142, and including an inorganic insulating material.

The touch sensor layer 150 may be arranged on the encapsulation layer 140.

The polarization layer 160 may be arranged on the touch sensor layer 150.

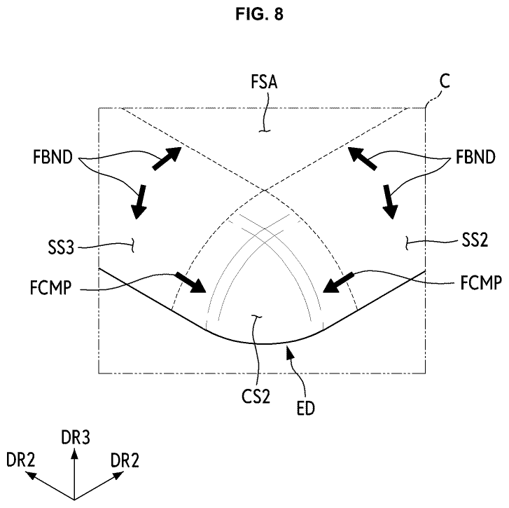

FIG. 8 is an enlarged view showing the part C of FIG. 1, according to one or more embodiments of the present disclosure.

First, as shown in FIGS. 1 and 4, the substrate 110 of the display panel 100 of the display device 10 according to one or more embodiments includes the main region MA including the flat display area FSA having a planar shape and the curved area CSA having a curved shape.

The edge BND of the main region MA may include the first side SD1 and the second side SD2 extending in the first direction DR1 and opposing each other in the second direction DR2, the third side SD3 and the fourth side SD4 extending in the second direction DR2 and opposing each other in the first direction DR1, and the corners ED connecting two sides.

The flat display area FSA may include the fifth side SD5 and the sixth side SD6 extending in the first direction DR1 and opposing each other in the second direction DR2, and the seventh side SD7 and the eighth side SD8 extending in the second direction DR2 and opposing each other in the first direction DR1.

The curved area CSA may include the first side area SS1 between the first side SD1 and the fifth side SD5, the second side area SS2 between the second side SD2 and the sixth side SD6, the third side area SS3 between the third side SD3 and the seventh side SD7, the fourth side area SS4 between the fourth side SD4 and the eighth side SD8, the first corner area CS1 in contact with a vertex between the fifth side SD5 and the seventh side SD7 and arranged between the first side area SS1 and the third side area SS3, the second corner area CS2 in contact with a vertex between the sixth side SD6 and the seventh side SD7 and arranged between the second side area SS2 and the third side area SS3, the third corner area CS3 in contact with a vertex between the sixth side SD6 and the eighth side SD8 and arranged between the second side area SS2 and the fourth side area SS4, and the fourth corner area CS4 in contact with a vertex between the fifth side SD5 and the eighth side SD8 and arranged between the first side area SS1 and the fourth side area SS4.

Each of the first side area SS1, the second side area SS2, the third side area SS3, the fourth side area SS4, the first corner area CS1, the second corner area CS2, the third corner area CS3, and the fourth corner area CS4 may include the peripheral display area PSA and the non-display area NDA.

The first side area SS1 may extend from the fifth side SD5 and be curved with a first curvature in a direction opposite to the direction in which light is emitted (e.g., the first curvature may be convex relative to the exterior surface of the display device 10).

The second side area SS2 may extend from the sixth side SD6 and be curved with a second curvature in a direction opposite to the direction in which light is emitted (e.g., the second curvature may be convex relative to the exterior surface of the display device 10). The second curvature may be in substantially the same range as (e.g., the amount of curvature may be substantially the same as) the first curvature.

The third side area SS3 may extend from the seventh side SD7 and be curved with a third curvature in a direction opposite to the direction in which light is emitted (e.g., the third curvature may be convex relative to the exterior surface of the display device 10). The third curvature may be in substantially the same or similar range as (e.g., the amount of curvature may be substantially the same as or similar to) the first curvature or the second curvature, but the present disclosure is not limited thereto.

The fourth side area SS4 may extend from the eighth side SD8 and be curved with a fourth curvature in a direction opposite to the direction in which light is emitted (e.g., the fourth curvature may be convex relative to the exterior surface of the display device 10). The fourth curvature may be in substantially the same range as (e.g., the amount of curvature may be substantially the same as) the third curvature.

The first corner area CS1 may be arranged between one side (end) of the first side area SS1 and one side (end) of the third side area SS3.

The first corner area CS1 may be a double curvature region that is curved with the first curvature of the first side area SS1 and the third curvature of the third side area SS3.

The second corner area CS2 may be arranged between one side (end) of the second side area SS2 and the other side (end) of the third side area SS3.

The second corner area CS2 may be a double curvature region that is curved with the second curvature of the second side area SS2 and the third curvature of the third side area SS3.

The third corner area CS3 may be arranged between the other side (end) of the second side area SS2 and one side (end) of the fourth side area SS4.

The third corner area CS3 may be a double curvature region that is curved with the second curvature of the second side area SS2 and the fourth curvature of the fourth side area SS4.

The fourth corner area CS4 may be arranged between the other side (end) of the first side area SS1 and the other side (end) of the fourth side area SS4.

The fourth corner area CS4 may be a double curvature region that is curved with the first curvature of the first side area SS1 and the fourth curvature of the fourth side area SS4.

Referring to FIG. 8, the second side area SS2 may extend from the sixth side SD6 and be curved with a second curvature in a direction opposite to the direction in which light is emitted (e.g., the second curvature may be convex relative to the exterior surface of the display device 10).

The third side area SS3 may extend from the seventh side SD7 and be curved with a third curvature in a direction opposite to the direction in which light is emitted (e.g., the third curvature may be convex relative to the exterior surface of the display device 10).

Each of the second side area SS2 and the third side area SS3 may be transformed into a curved shape by (e.g., may be curved due to) a tensile force FBND.

The second corner area CS2 may be a double curvature region that is curved with the second curvature of the second side area SS2 and the third curvature of the third side area SS3.

For example, the second corner area CS2 may be transformed into a double curvature shape by a compressive force FCMP in a direction toward the corner ED between the second side SD2 and the third side SD3 from each of the second side area SS2 and the third side area SS3.

In the second corner area CS2, the closer the portion is to the corner ED, the more strongly the compressive force FCMP may act. If the edge of the display panel 100 fails to withstand the compressive stress, buckling defects, in which a portion of the edge of the display panel 110 adjacent to the corner ED becomes unevenly crumpled, may occur.

Accordingly, the method for manufacturing the display device 10 according to one or more embodiments effectively addresses this issue by providing the display panel 100 that can be transformed into a shape with a curved edge, while still mitigating the buckling defects.

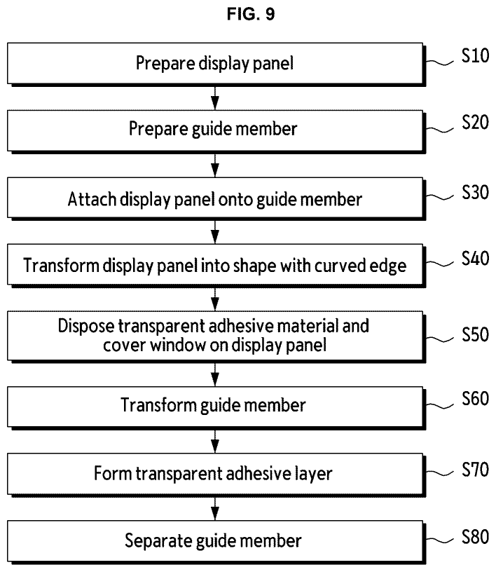

FIG. 9 is a flowchart illustrating a method for manufacturing the display device according to one or more embodiments of the present disclosure.

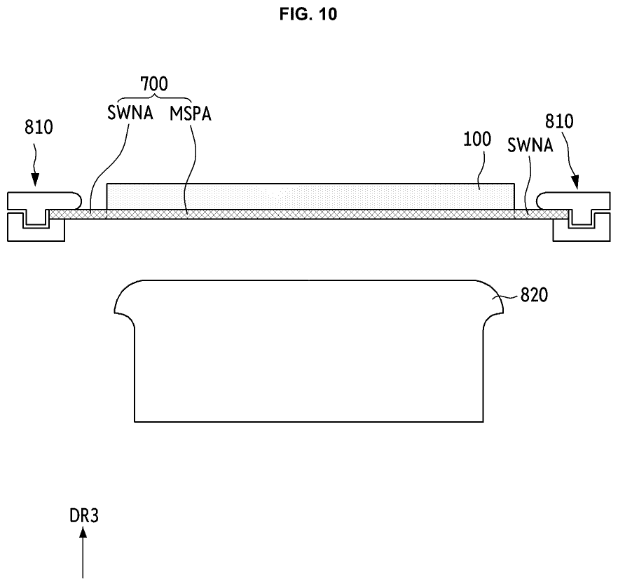

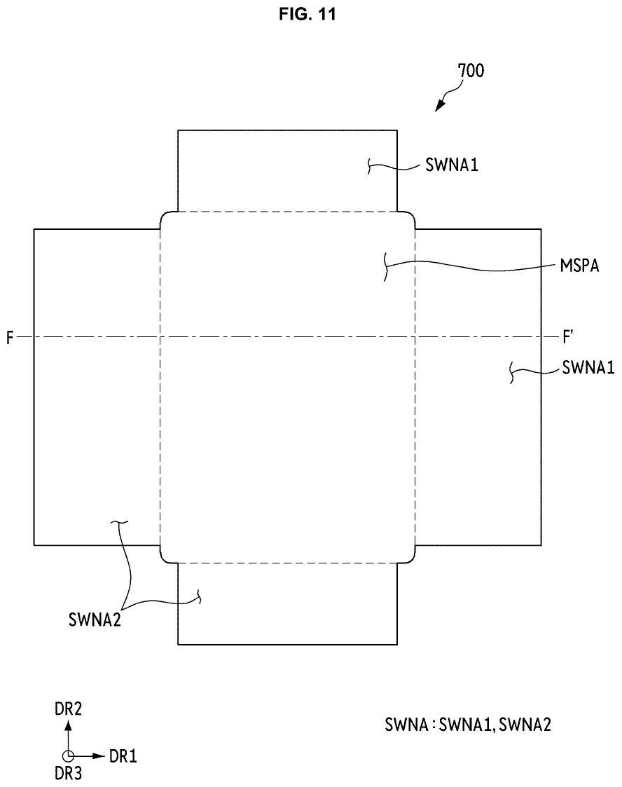

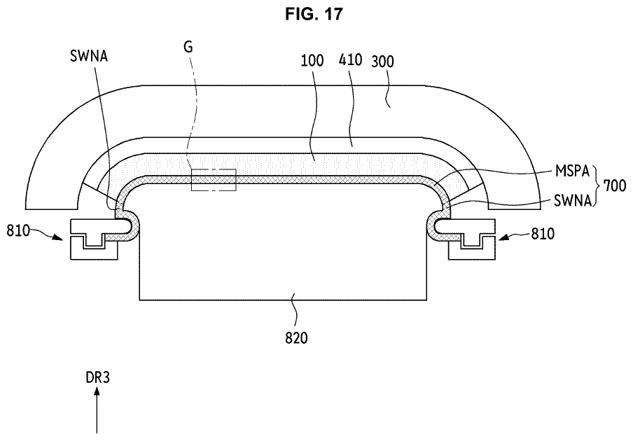

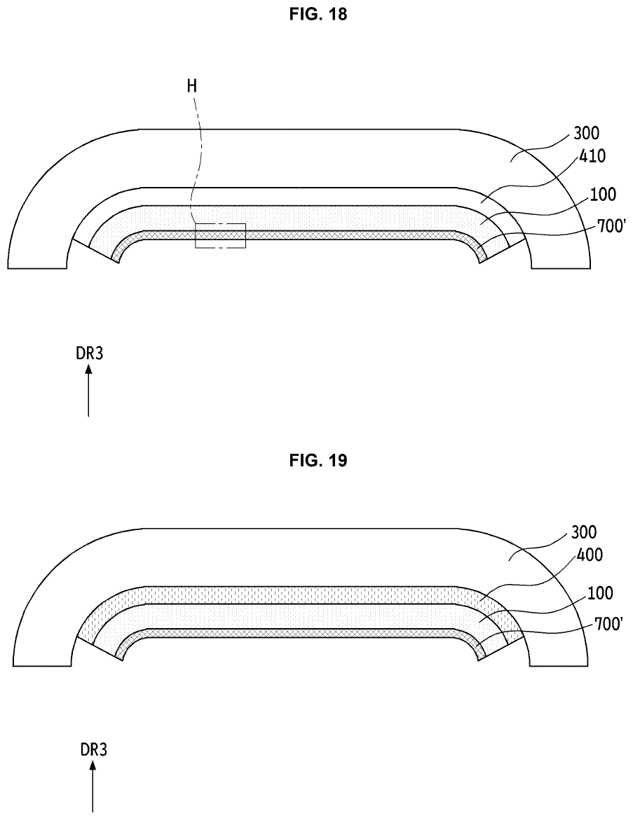

Referring to FIG. 9, the method for manufacturing the display device 10 according to one or more embodiments may include: preparing the display panel 100 (see, e.g., FIG. 10) of a flat plate shape that is to emit light for image display (step (e.g., act or task) S10); preparing a guide member 700 (see, e.g., FIG. 10) that includes a main support area MSPA (see, e.g., FIG. 11) facing (e.g., overlapping) the display panel 100 and two or more sub-wing areas SWNA extending from the edge of the main support area MSPA (step (e.g., act or task) S20); attaching the display panel 100 onto the guide member 700 (step (e.g., act or task) S30); transforming the display panel 100 from a flat plate shape into a shape with a curved edge by using the guide member 700 and a mold member 820 (see, e.g., FIG. 10) arranged below the guide member 700 (step (e.g., act or task) S40); disposing a transparent adhesive material 410 (see, e.g., FIG. 17) and the cover window 300 (see, e.g., FIG. 17) on the display panel 100 (step (e.g., act or task) S50); transforming the guide member 700 (step (e.g., act or task) S60); curing the transparent adhesive material 410 to form the transparent adhesive layer 400 (see, e.g., FIG. 19) that fixes the display panel 100 to the cover window 300 (step (e.g., act or task) S70); and separating a guide member 700′ (see, e.g., FIG. 18) from the display panel 100 (step (e.g., act or task) S80).

As shown in FIGS. 3, 4, and 5, according to one or more embodiments, in step (e.g., act or task) S10 of preparing the display panel 100, the display panel 100 may include the substrate 110, the circuit layer 120 arranged on the substrate 110, and the element layer 130 arranged on the circuit layer 120.

The substrate 110 may include the main region MA including the display area DA where the emission areas EA are arranged, and the non-display area NDA arranged around the display area DA.

The edge BND of the main region MA may include the first side SD1 and the second side SD2 extending in the first direction DR1, the first and second sides SD1 and SD2 opposing each other in the second direction DR2, the third side SD3 and the fourth side SD4 extending in the second direction DR2, the third and the fourth sides SD3 and SD4 opposing each other in the first direction DR1, and the corners ED connecting two sides. In other words, the corners ED may be at each intersection between the first, second, third, and fourth sides SD1, SD2, SD3, and SD4, and connecting the sides at each intersection. For example, one corner ED may connect an end of the first side SD1 to an end of the fourth side SD4, one corner ED may connect another end of the fourth side SD4 to an end of the second side SD2, one corner ED may connect another end of the second side SD2 to an end of the third side SD3, and one corner ED may connect another end of the third side SD3 to another end of the first side SD1.

Each of the corners ED may connect one of the first and/or second sides SD1 and SD2 to one of the third and/or fourth sides SD3 and SD4.

The element layer 130 may include the light emitting elements LE (see, e.g., FIGS. 6 and 7) arranged in the emission areas EA.

The circuit layer 120 may include the light emitting pixel drivers EPD electrically connected to the light emitting elements LE.

FIG. 10 is a cross-sectional view illustrating a mold member and a process diagram of the step (e.g., act or task) of attaching the display panel onto the guide member of FIG. 9, according to one or more embodiments of the present disclosure.

Referring to FIG. 10, the guide member 700 may include the main support area MSPA facing (e.g., overlapping) the display panel 100, and the two or more sub-wing areas SWNA extending from the edge of the main support area MSPA. For example, the main support area MSPA may overlap the display panel 100 in a plan view.

The display panel 100 may be attached onto the main support area MSPA of the guide member 700.

Additionally, the guide member 700 may be aligned above the mold member 820, while being fixed to a clamp 810 that holds the two or more sub-wing areas SWNA.

FIGS. 11, 12, and 13 are each a plan view showing the guide member of FIG. 10 according to one or more embodiments of the present disclosure.

As shown in FIGS. 11, 12, and 13, the guide member 700 may include the main support area MSPA and the two or more sub-wing areas SWNA.

The two or more sub-wing areas SWNA may include one or more first sub-wing areas SWNA1 extending from one side of the edge of the main support area MSPA, and one or more second sub-wing areas SWNA2 extending from another side of the edge of the main support area MSPA and opposing the one or more first sub-wing areas SWNA1.

In one example, as shown in FIG. 11, the guide member 700 may include four sub-wing areas SWNA extending from four sides of the edge of the main support area MSPA. The four sub-wing areas SWNA may include two first sub-wing areas SWNA1 and two second sub-wing areas SWNA2 that oppose each other in the first direction DR1 or the second direction DR2.

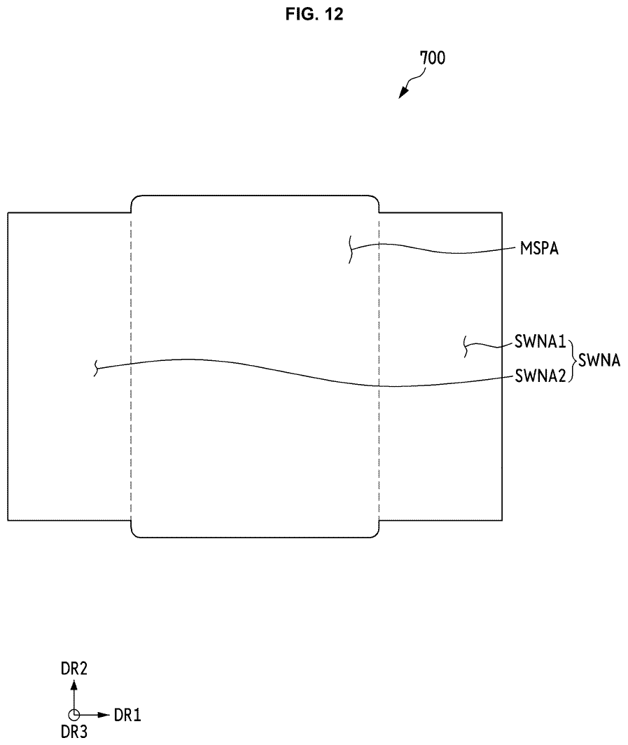

Alternatively, in one or more embodiments, as shown in FIG. 12, the guide member 700 may include two sub-wing areas SWNA extending from two sides of the edge of the main support area MSPA and opposing each other. The two sub-wing areas SWNA may include one first sub-wing area SWNA1 and one second sub-wing area SWNA2 that oppose each other in the first direction DR1 or the second direction DR2.

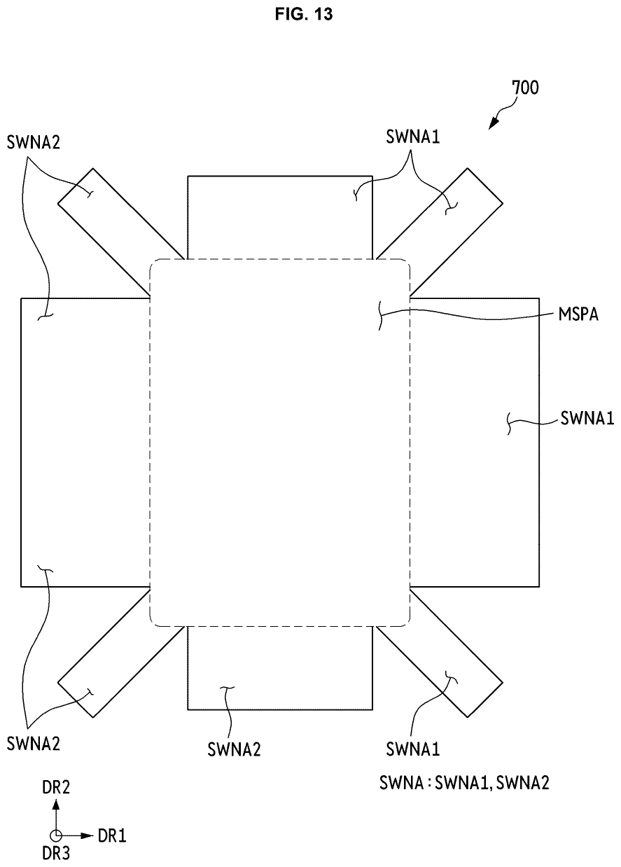

Alternatively, in one or more embodiments, as shown in FIG. 13, the guide member 700 may include eight sub-wing areas SWNA extending from four sides and four vertices of the edge of the main support area MSPA. The eight sub-wing areas SWNA may include two first sub-wing areas SWNA1 and two second sub-wing areas SWNA2 that oppose each other in the first direction DR1 or the second direction DR2, and two first sub-wing areas SWNA1 and two second sub-wing areas SWNA2 that oppose each other in a diagonal direction intersecting the first direction DR1 and the second direction DR2.

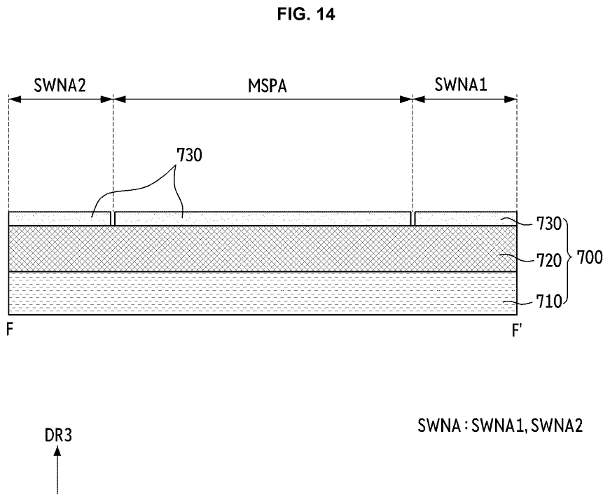

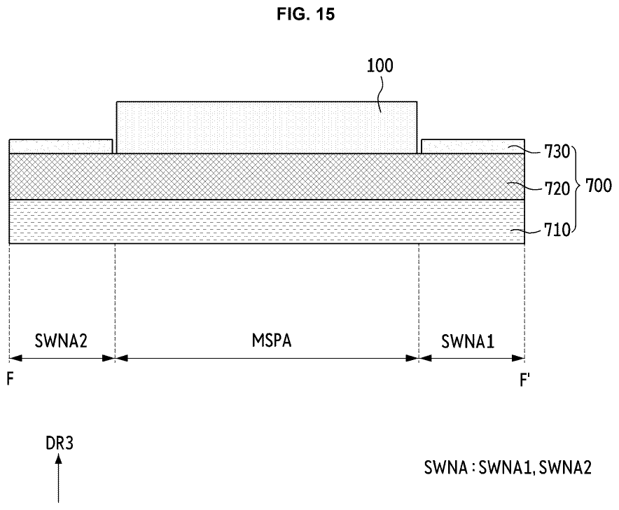

FIG. 14 is a cross-sectional view taken along the line F-F′ of FIG. 11, according to one or more embodiments of the present disclosure. FIG. 15 is a process diagram illustrating the step (e.g., act or task) of attaching the display panel onto the guide member of FIG. 9, according to one or more embodiments of the present disclosure, for example, one or more embodiments of FIG. 14. FIG. 15 shows a cross-sectional view taken along the line F-F′ of FIG. 11 during the manufacturing process, according to one or more embodiments of the present disclosure.

As shown in FIG. 14, according to one or more embodiments, in step (e.g., act or task) S20 of preparing the guide member 700, the guide member 700 may include a guide support layer 710 including the main support area MSPA and the two or more sub-wing areas SWNA, a guide adhesive layer 720 arranged on the guide support layer 710, and a cover layer 730 arranged on the guide adhesive layer 720.

A portion of the cover layer 730 that overlaps the two or more sub-wing areas SWNA may be separated from the remaining portion that overlaps the main support area MSPA.

Accordingly, the remaining portion of the cover layer 730 that overlaps the main support area MSPA may be easily delaminated from the guide adhesive layer 720. In such embodiments, the portion of the cover layer 730 that overlaps the two or more of the sub-wing areas SWNA may remain on the guide adhesive layer 720.

As shown in FIG. 15, in step (e.g., act or task) S30 of attaching the display panel 100 onto the guide member 700, the display panel 100 may be attached onto the main support area MSPA of the guide adhesive layer 720 that has been exposed by removing the remaining portion of the cover layer 730 that overlaps the main support area MSPA.

In such embodiments, the cover layer 730 may cover the two or more sub-wing areas SWNA of the guide adhesive layer 720.

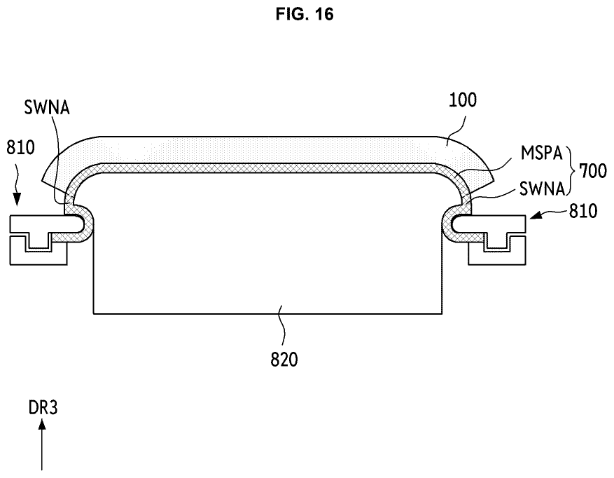

FIGS. 16, 17, 18, 19, and 20 are process diagrams illustrating some of the steps (e.g., acts or tasks) of FIG. 9, according to one or more embodiments of the present disclosure.

Referring to FIG. 16, in step (e.g., act or task) S40 of transforming the display panel 100, the clamp 810 holding the two or more sub-wing areas SWNA of the guide member 700 may be moved to allow the guide member 700 to be arranged on the mold member 820.

Then, by pulling the two or more sub-wing areas SWNA of the guide member 700 toward the underside of the mold member 820 or pushing them to the side of the mold member 820 using the clamp 810, the main support area MSPA of the guide member 700 and the display panel 100 may be transformed into a shape with a curved edge, conforming to the mold member 820.

As shown in FIGS. 1 and 2, after step (e.g., act or task) S40 of transforming the display panel 100, the display panel 100 may be transformed into a shape with a curved edge.

Accordingly, the main region MA of the display panel 100 may include the flat display area FSA having a planar shape, and the curved area CSA arranged around the flat display area FSA and having a curved shape.

The curved area CSA may include the peripheral display area PSA arranged around the flat display area FSA, and the non-display area NDA arranged between the peripheral display area PSA and the edge BND of the main region MA.

The flat display area FSA may include the fifth side SD5 and the sixth side SD6 extending in the first direction DR1 and opposing each other in the second direction DR2, and the seventh side SD7 and the eighth side SD8 extending in the second direction DR2 and opposing each other in the first direction DR1.

The curved area CSA may include side areas in contact with the sides of the flat display area FSA and corner areas in contact with the vertices of the flat display area FSA.

The side areas may include the first side area SS1 between the first side SD1 and the fifth side SD5, the second side area SS2 between the second side SD2 and the sixth side SD6, the third side area SS3 between the third side SD3 and the seventh side SD7, and the fourth side area SS4 between the fourth side SD4 and the eighth side SD8.

The corner areas may include the first corner area CS1 in contact with a vertex between the fifth side SD5 and the seventh side SD7 and arranged between the first side area SS1 and the third side area SS3, the second corner area CS2 in contact with a vertex between the sixth side SD6 and the seventh side SD7 and arranged between the second side area SS2 and the third side area SS3, the third corner area CS3 in contact with a vertex between the sixth side SD6 and the eighth side SD8 and arranged between the second side area SS2 and the fourth side area SS4, and the fourth corner area CS4 in contact with a vertex between the fifth side SD5 and the eighth side SD8 and arranged between the first side area SS1 and the fourth side area SS4.

As shown in FIG. 17, in step (e.g., act or task) S50 of disposing the transparent adhesive material 410 and the cover window 300 on the display panel 100, the transparent adhesive material 410 may be applied onto the display panel 100 that has been transformed using the guide member 700 and the mold member 820, and the cover window 300 having a curved edge may be arranged on the transparent adhesive material 410.

As shown in FIG. 18, in step (e.g., act or task) S60 of transforming the guide member 700, the guide member 700 may be transformed after removing the mold member 820 (see, e.g., FIG. 17) arranged below the guide member 700, and releasing the connection between the guide member 700 and the clamp 810 (see, e.g., FIG. 17). The transformed guide member 700′ may have a shape in which the two or more of the sub-wing areas SWNA do not protrude outside the display panel 100.

As shown in FIG. 19, in step (e.g., act or task) S70 of curing the transparent adhesive material 410 (see, e.g., FIG. 18) to form the transparent adhesive layer 400, the transparent adhesive layer 400 that fixes the display panel 100 to the cover window 300 may be formed by exposing the curing material of the transparent adhesive material 410 to a curing medium while the transformed guide member 700′ remains beneath the display panel 100.

In such embodiments, because the guide member 700′ remains beneath the display panel 100, the rigidity of the display panel 100 may be reinforced by the guide member 700′. Thus, the strength of the display panel 100 may be enhanced, and thus, buckling defects caused by the double curvature shape may be reduced.

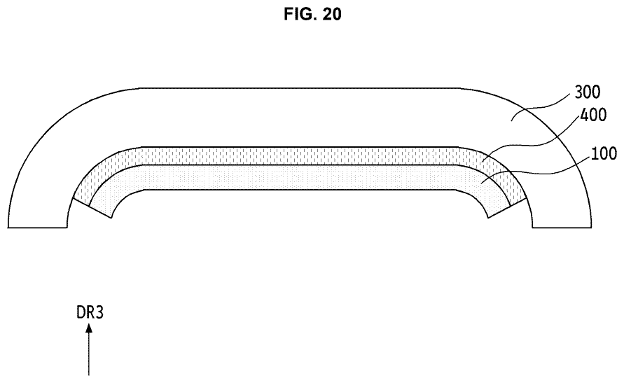

As shown in FIG. 20, in step (e.g., act or task) S80 of separating the guide member 700′, the transformed guide member 700′ may be removed from the display panel 100 which has been bonded to the cover window 300 through the transparent adhesive layer 400.

As described above, according to one or more embodiments, because the transparent adhesive material 410 (see, e.g., FIG. 18) is cured while the rigidity of the display panel 100 is reinforced by the guide member 700′ remaining beneath the display panel 100, buckling defects may be reduced.

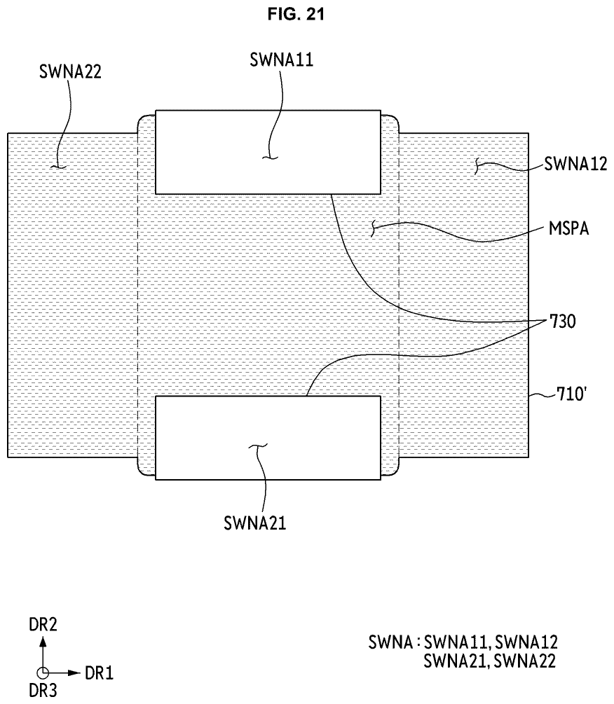

FIGS. 21, 22, 23, and 24 are process diagrams illustrating the step of transforming the guide member of FIG. 9 according to one or more embodiments of the present disclosure.

According to one or more embodiments as shown, for example, in FIG. 14, the guide member 700 may include the guide support layer 710 including the main support area MSPA and the two or more sub-wing areas SWNA, the guide adhesive layer 720 arranged on the guide support layer 710, and the cover layer 730 covering the two or more sub-wing areas SWNA of the guide adhesive layer 720.

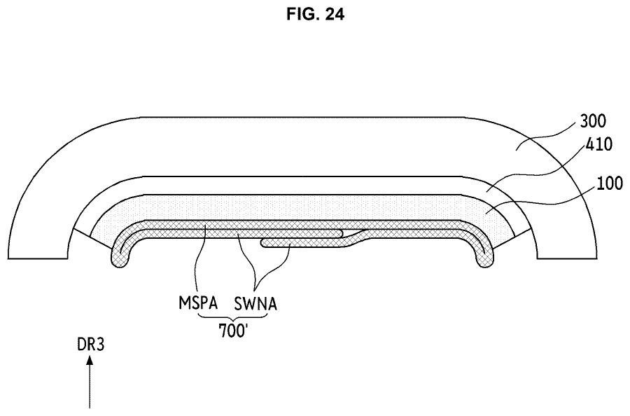

Additionally, as shown in FIG. 24, according to one or more embodiments as shown, for example, in FIG. 14, in step (e.g., act or task) S60 of transforming the guide member 700, the two or more sub-wing areas SWNA of the guide member 700 may be accommodated under a rear surface 710′ (see, e.g., FIGS. 21 to 23) of the guide support layer 710 and overlap the main support area MSPA.

FIGS. 21, 22, and 23 illustrate process diagrams of step (e.g., act or task) S60 of transforming the guide member 700, if (e.g., when) the guide member 700 includes four sub-wing areas SWNA according to one or more embodiments as shown, for example, in FIG. 11.

For example, as shown in FIG. 21, step (e.g., act or task) S60 of transforming the guide member 700 may include folding a pair including a first sub-wing area SWNA11 and a second sub-wing area SWNA21 that oppose each other in one of the first direction DR1 or the second direction DR2 (e.g., the second direction DR2 in FIG. 21), with respect to the edge of the main support area MSPA, and disposing them on the rear surface 710′ of the guide support layer.

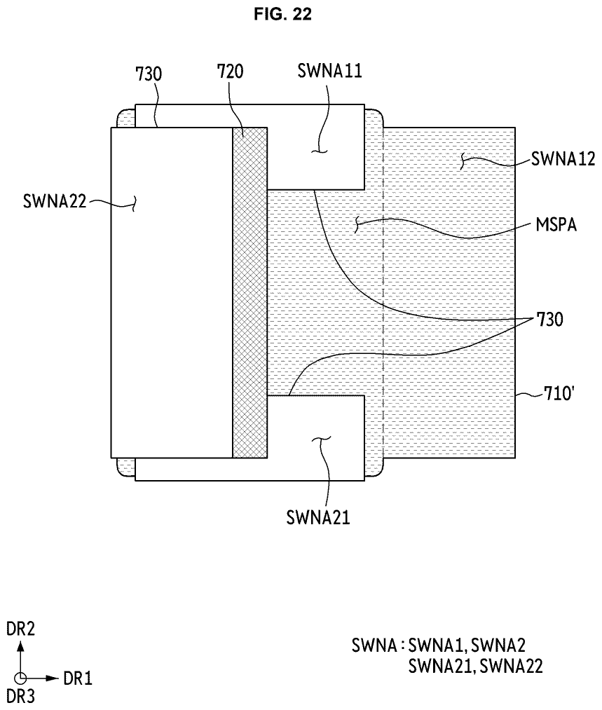

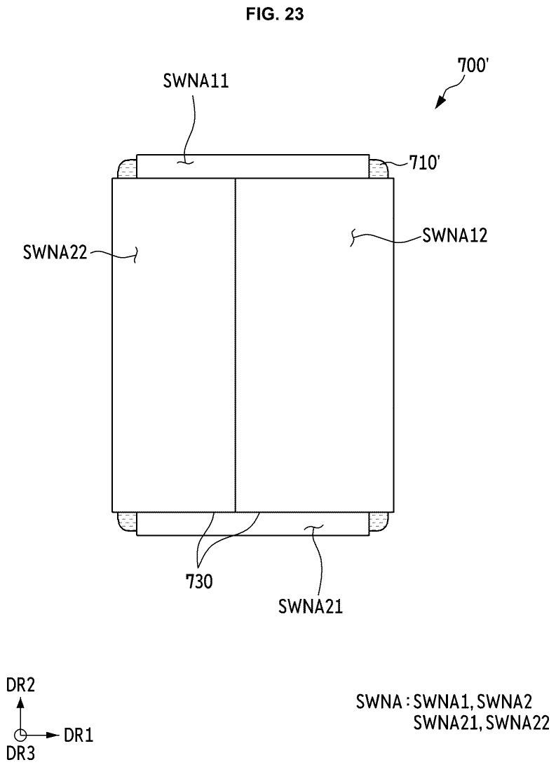

As shown in FIGS. 22 and 23, step (e.g., act or task) S60 of transforming the guide member 700 may include folding a pair including a first sub-wing area SWNA12 and a second sub-wing area SWNA22 that oppose each other in the other of the first direction DR1 or the second direction DR2 (e.g., the first direction DR1 in FIG. 22), with respect to the edge of the main support area MSPA, and disposing them on the rear surface 710′ of the guide support layer.

In such embodiments, as shown in FIG. 22, the cover layer 730 may be removed and the guide adhesive layer 720 may be exposed in a portion of one of the first sub-wing area SWNA12 and/or the second sub-wing area SWNA22 that oppose each other in the first direction DR1 (e.g., the cover layer 730 may be removed and the guide adhesive layer 720 may be exposed in a portion of the second sub-wing area SWNA22, as shown in FIG. 22). The cover layer 730 may be removed and the guide adhesive layer 720 may be exposed in a portion of the sub-wing area that is folded first and arranged on the rear surface 710′ of the guide support layer.

Additionally, as shown in FIG. 23, the other one (e.g., the first sub-wing area SWNA12 in FIG. 23) of the pair of the first sub-wing area SWNA12 and the second sub-wing area SWNA22 that oppose each other in the first direction DR1, which is folded later, may be fixed to the one (i.e., the second sub-wing area SWNA22) that has been folded first, through the exposed guide adhesive layer 720.

Thus, as shown in FIG. 24, after the step (e.g., act or task) S60 of transforming the guide member 700, the transformed guide member 700′ may entirely overlap the display panel 100 and/or the cover glass 300.

In this manner, without replacing the guide member 700, the guide member 700 may be used to reinforce the display panel 100 in step (e.g., act or task) S70 of forming the transparent adhesive layer 400. In other words, the guide member may reinforce the display panel 100 to help reduce the effects of physical stress on the display panel.

Additionally, according to one or more embodiments of FIG. 14, in order to prevent or reduce the guide adhesive layer 720 from being softened in step (e.g., act or task) S70 of forming the transparent adhesive layer 400, the guide adhesive layer 720 may contain a curing material different from that of the transparent adhesive layer 400.

In one or more embodiments, the transparent adhesive layer 400 may contain a curing material that is cured by light, and the guide adhesive layer 720 may contain a curing material that is softened by heat.

In other embodiments, the transparent adhesive layer 400 may contain a curing material that is cured by light in the first wavelength band, and the guide adhesive layer 720 may contain a curing material that is softened by light in the second wavelength band different from the first wavelength band.

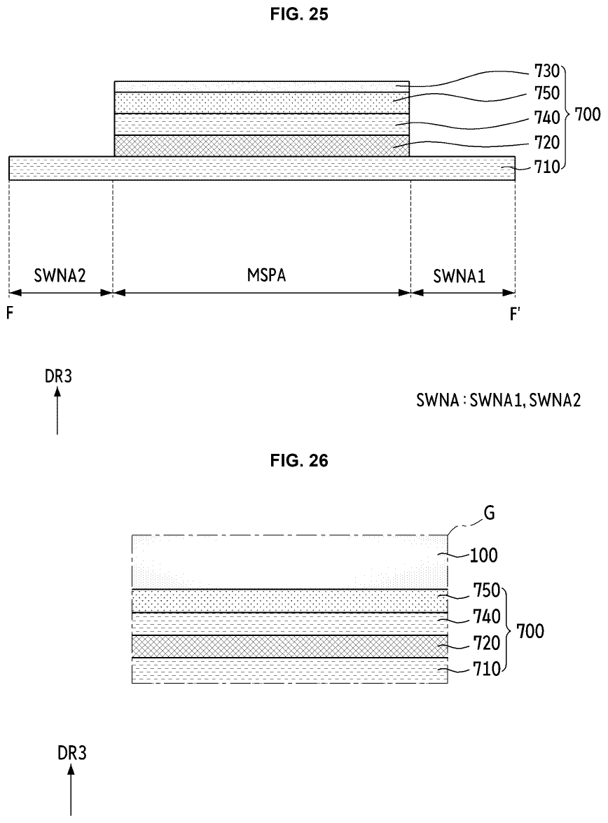

FIG. 25 is a cross-sectional view taken along the line F-F′ of FIG. 11 according to one or more embodiments of the present disclosure. FIGS. 26, 27, 28, and 29 are process diagrams illustrating some of the steps of FIG. 9 according to one or more embodiments of the present disclosure as shown, for example in FIG. 25.

The guide member 700 according to one or more embodiments of FIG. 25 may include the guide support layer 710 including the main support area MSPA and the two or more sub-wing areas SWNA, the guide adhesive layer 720 arranged on the main support area MSPA of the guide support layer 710, an additional support layer 740 arranged on the guide adhesive layer 720, and an additional adhesive layer 750 arranged on the additional support layer 740.

In step (e.g., act or task) S20 of preparing the guide member 700, the guide member 700 may further include the cover layer 730 that covers the additional adhesive layer 750.

According to one or more embodiments of FIG. 25, in order to prevent or reduce the likelihood of the transparent adhesive layer 400 being softened together with the guide adhesive layer 720 in step (e.g., act or task) S60 of transforming the guide member 700, the guide adhesive layer 720 may contain a curing material different from that of the transparent adhesive layer 400.

Additionally, in order to prevent or reduce the likelihood of the additional adhesive layer 750 being softened together with the guide adhesive layer 720 in step (e.g., act or task) S60 of transforming the guide member 700 and from being softened by the curing condition of the transparent adhesive material 410 in step (e.g., act or task) S70 of forming the transparent adhesive layer 400, the additional adhesive layer 750 may contain a curing material different from that of each of the guide adhesive layer 720 and the transparent adhesive layer 400.

In one or more embodiments, the transparent adhesive layer 400 may contain a curing material that is cured by light in the first wavelength band, the guide adhesive layer 720 may contain a curing material that is softened by heat, and the additional adhesive layer 750 may contain a curing material that is softened by light in the second wavelength band different from the first wavelength band.

In other embodiments, the transparent adhesive layer 400 may contain a curing material that is cured by light in the first wavelength band, the guide adhesive layer 720 may contain a curing material that is softened by light in the second wavelength band different from the first wavelength band, and the additional adhesive layer 750 may contain a curing material that is softened by light in the third wavelength band different from each of the first and second wavelength bands.

FIG. 26 illustrates the part G of FIG. 17 showing step (e.g., act or task) S40 of transforming the display panel 100, according to one or more embodiments of the present disclosure as shown, for example, in FIG. 25.

As shown in FIG. 26, in step (e.g., act or task) S30 of attaching the display panel 100 onto the guide member 700, the display panel 100 may be attached onto the additional adhesive layer 750 exposed by the removal of the cover layer 730.

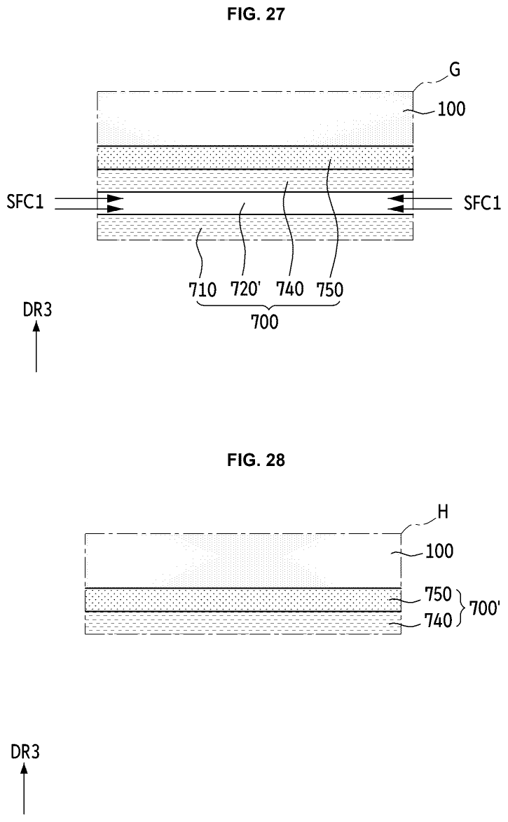

FIG. 27 is a process diagram of step (e.g., act or task) S60 of transforming the guide member 700, according to one or more embodiments of the present disclosure as shown, for example, in FIG. 25.

FIG. 28 illustrates the part H of FIG. 18 showing the guide member 700′ after step (e.g., act or task) S60 of transforming the guide member 700, according to one or more embodiments of the present disclosure as shown, for example, in FIG. 25.

As shown in FIGS. 27 and 28, according to one or more embodiments of FIG. 25, in step (e.g., act or task) S60 of transforming the guide member 700, the guide adhesive layer 720 may be softened, allowing the guide adhesive layer 720 and the guide support layer 710 to be delaminated.

As shown in FIG. 27, in the step (e.g., act or task) S60 of transforming the guide member 700, the guide adhesive layer 720 may be softened by exposing a guide member 700 to a first softening condition SFC1 corresponding to the curing material of the guide adhesive layer 720.

Additionally, as shown in FIG. 28, as the softened guide adhesive layer 720 is delaminated from the additional support layer 740, the guide support layer 710 including the two or more sub-wing areas SWNA may be removed together with the guide adhesive layer 720.

Thus, the guide member 700′ after step (e.g., act or task) S60 of transforming the guide member 700 includes the additional adhesive layer 750 and the additional support layer 740.

Further, in step (e.g., act or task) S70 of forming the transparent adhesive layer 400, the strength of the display panel 100 may be reinforced by the additional support layer 740 remaining beneath the display panel 100, thereby reducing buckling defects, such as those caused by stress.

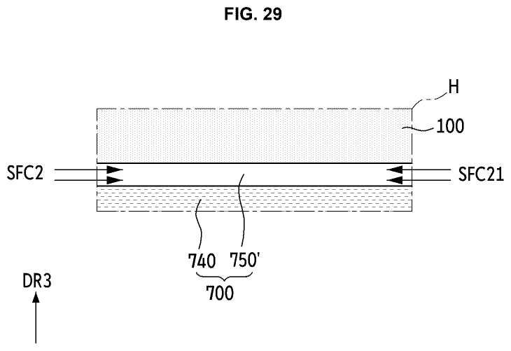

FIG. 29 is a process diagram of step (e.g., act or task) S80 of separating the guide member 700′, according to one or more embodiments of the present disclosure as shown, for example, in FIG. 25.

As shown in FIG. 29, in step (e.g., act or task) S80 of separating the guide member 700′, the guide member 700 may be exposed to a second softening condition SFC2 corresponding to the curing material of the additional adhesive layer 750, thereby softening the additional adhesive layer 750.

Accordingly, the additional support layer 740 may be delaminated from the display panel 100 together with the softened additional adhesive layer 750, thereby allowing the guide member 700′ to be removed from the display panel 100.

As described above, according to one or more embodiments as shown, for example, in FIG. 25, the guide member 700 includes the additional support layer 740 and the additional adhesive layer 750 for reinforcing the strength of the display panel 100, in addition to the guide support layer 710 and the guide adhesive layer 720 for transforming the display panel 100.

Because the additional support layer 740 has a flat plate shape similar to the guide support layer 710, stress reinforcement (e.g., reinforcement to reduce the effects of stress) by the additional support layer 740 may be applied relatively uniformly (e.g., substantially uniformly) across the entire display panel 100.

Further, the process of softening the guide adhesive layer 720 may be simpler than the process of folding the two or more sub-wing areas SWNA, which may be advantageous for simplifying the manufacturing process of the display device 10.

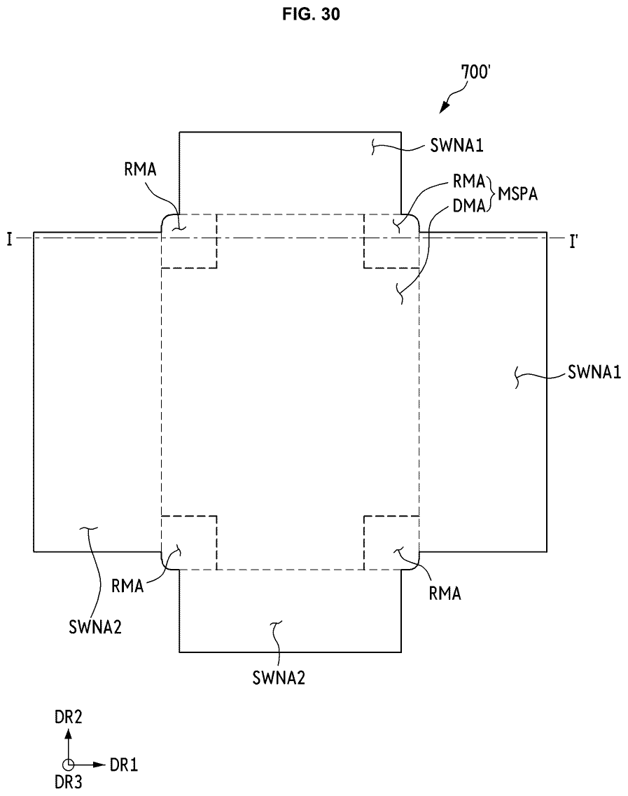

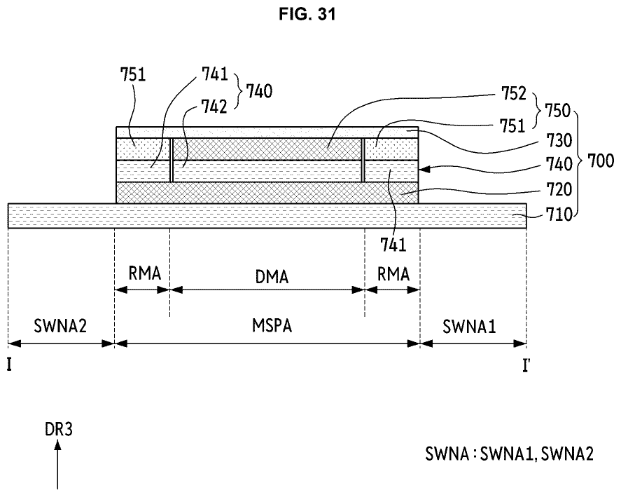

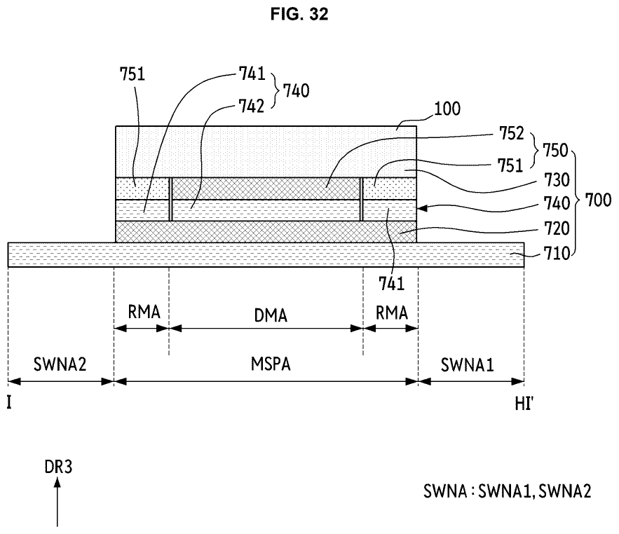

FIG. 30 is a plan view showing a guide member according to one or more embodiments of the present disclosure. FIG. 31 is a plan view taken along the line I-I′ of FIG. 30, according to one or more embodiments of the present disclosure. FIGS. 32 to 35 are process diagrams illustrating some of the steps (e.g., acts or tasks) of FIG. 9 according to one or more embodiments of the present disclosure as shown, for example, in FIGS. 30 and 31.

Referring to FIG. 30, the main support area MSPA of the guide member 700 according to one or more embodiments may include residual areas RMA that face some areas of the main region MA adjacent to the corners ED, and a dummy area DMA that is the remainder excluding the residual areas RMA.

As shown in FIG. 31, according to one or more embodiments, the guide member 700 may include the guide support layer 710 including the main support area MSPA and the two or more sub-wing areas SWNA, the guide adhesive layer 720 arranged on the main support area MSPA of the guide support layer 710, an additional support layer 740 arranged on the guide adhesive layer 720, and an additional adhesive layer 750 arranged on the additional support layer 740.

In step (e.g., act or task) S20 of preparing the guide member 700, the guide member 700 may further include the cover layer 730 that covers the additional adhesive layer 750.

Each of the additional support layer 740 and the additional adhesive layer 750 may include residual portions 741, 751 that face some areas of the main region MA adjacent to the corners ED, and a dummy portion 742, 752 that faces the remaining area excluding the some areas of the main region MA and that is spaced and/or apart (e.g., spaced apart or separated) from the residual portions 741, 751.

For example, the residual portions 741, 751 of each of the additional support layer 740 and the additional adhesive layer 750 may be arranged in the residual area RMA of the main support area MSPA, and the dummy portion 742, 752 of each of the additional support layer 740 and the additional adhesive layer 750 may be arranged in the dummy area DMA of the main support area MSPA.

According to one or more embodiments of FIGS. 30 and 31, in order to prevent or reduce the likelihood of the transparent adhesive layer 400 being softened together with the guide adhesive layer 720 in step (e.g., act or task) S60 of transforming the guide member 700, the guide adhesive layer 720 may contain a curing material different from that of the transparent adhesive layer 400.

According to one or more embodiments of FIGS. 30 and 31, the dummy portion 752 of the additional adhesive layer 750 may contain substantially the same curing material as that of the guide adhesive layer 720, such that it is softened together with the guide adhesive layer 720 in step (e.g., act or task) S60 of transforming the guide member 700.

Additionally, the residual portions 751 of the additional adhesive layer 750 may contain a curing material different from that of each of the guide adhesive layer 720 and the transparent adhesive layer 400, in order to prevent or reduce the likelihood of them being softened together with the guide adhesive layer 720 in the step (e.g., act or task) S60 of transforming the guide member 700 and from being softened by the curing condition of the transparent adhesive material 410 in the step (e.g., act or task) S70 of forming the transparent adhesive layer 400.

As shown in FIG. 32, in step (e.g., act or task) S30 of attaching the display panel 100 onto the guide member 700, the display panel 100 may be attached onto the residual portions 751 and the dummy portion 752 of the additional adhesive layer 750.

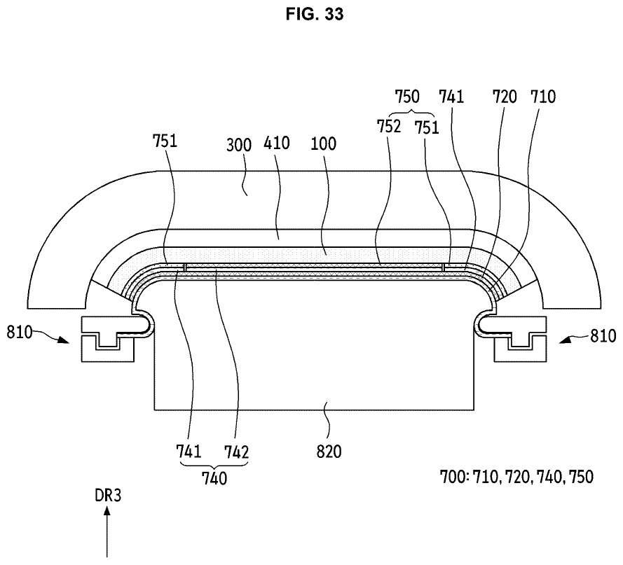

As shown in FIG. 33, in step (e.g., act or task) S40 of transforming the display panel 100, the main support area MSPA of the guide member 700 and the display panel 100 may be transformed into a shape with a curved edge conforming to the mold member 820, by pulling the guide support layer 710 of the guide member 700 toward the underside of the mold member 820 or pushing it to the side of the mold member 820 using the clamp 810.

Then, in step (e.g., act or task) S50 of disposing the transparent adhesive material 410 and the cover window 300, the transparent adhesive material 410 and the cover window 300 may be sequentially arranged on the transformed display panel 100.

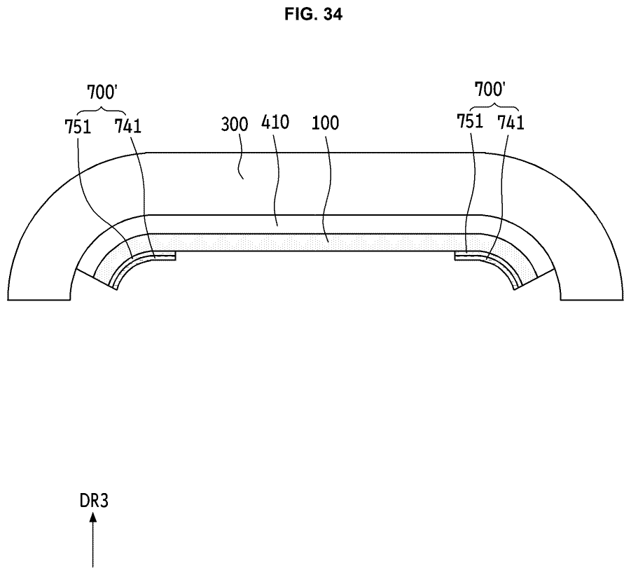

As shown in FIG. 34, in step (e.g., act or task) S60 of transforming the guide member 700, the dummy portion 752 of the additional adhesive layer 750 may be softened together with the guide adhesive layer 720. As a result, the guide adhesive layer 720 and the guide support layer 710 adhered thereto, and the dummy portion 752 of the additional adhesive layer 750 and the dummy portion 742 of the additional support layer 740 adhered thereto may be removed.

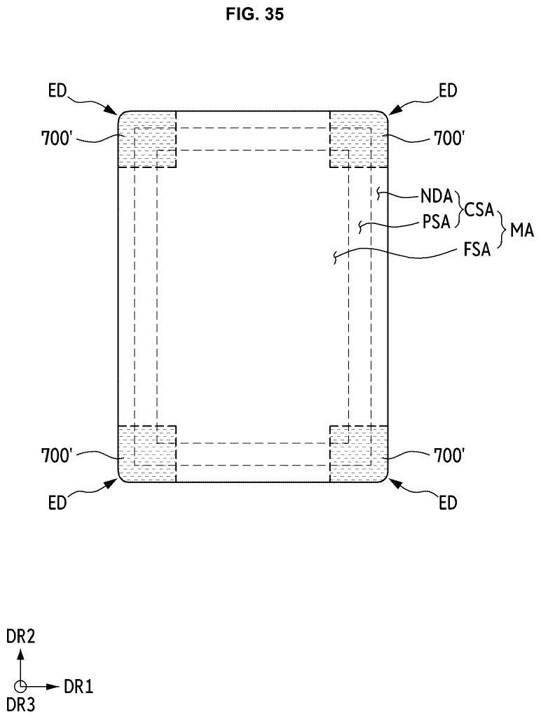

Thus, as shown in FIG. 35, the guide member 700′ after step (e.g., act or task) S60 of transforming the guide member 700 includes only the residual portions 741 and 751 adjacent to the corners ED of the main region MA.

For example, the residual portions 741 and 751 of the transformed guide member 700′ may face (e.g., overlap) the first, second, third, and fourth corner areas CS1, CS2, CS3, and CS4 (see, e.g., FIG. 1), which become double curvature regions of the main region MA.

Accordingly, in step (e.g., act or task) S70 of forming the transparent adhesive layer 400, the first, second, third, and fourth corner areas CS1, CS2, CS3, and CS4 (see, e.g. FIG. 1), which become double curvature regions of the display panel 100, may have a rigidity reinforced by the residual portions 741 and 751 of the transformed guide member 700′, so that buckling defects caused by the compressive force FCMP (see, e.g., FIG. 8) may be reduced.

Furthermore, because the transformed guide member 700′ does not face the first, second, third, and fourth side areas SS1, SS2, SS3, and SS4 (see FIG. 1) of the display panel 100, the magnitude of the tensile force FBND (see, e.g., FIG. 8) desired or required for the transformation of the first, second, third, and fourth side areas SS1, SS2, SS3, and SS4 (see, e.g., FIG. 1) may not increase.

The display device, electronic apparatus, device for manufacturing the display device, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A method comprising:
preparing a display panel having a flat plate shape that is configured to emit light for image display;
preparing a guide member comprising a main support area overlapping the display panel and two or more sub-wing areas extending from an edge of the main support area;
attaching the display panel onto the guide member;
placing a mold member below the guide member;
transforming the display panel from the flat plate shape into a shape with a curved edge by utilizing the guide member and the mold member;
disposing a transparent adhesive material and a cover window on the display panel;
transforming the guide member;
curing the transparent adhesive material to form a transparent adhesive layer that fixes the display panel to the cover window; and
separating the guide member from the display panel,
wherein the method is for manufacturing a display device.

2. The method of claim 1,
wherein in the preparing of the display panel, the display panel comprises:
a substrate;
a circuit layer on the substrate; and
an element layer on the circuit layer, and
wherein after the transforming of the display panel,
the substrate comprises:
a flat display area having a planar shape; and
a curved area around the flat display area and having a curved shape, the curved area comprising a peripheral display area around the flat display area; and a non-display area around the peripheral display area, and
the display panel comprises:
emission areas to emit the light in the flat display area and the peripheral display area, and
the element layer comprises light emitting elements in the emission areas.

3. The method of claim 2, wherein the two or more sub-wing areas comprise:
one or more first sub-wing areas extending from one edge of the main support area; and
one or more second sub-wing areas extending from another edge of the main support area that is opposite to the one or more first sub-wing areas, and
the transforming of the display panel comprises pulling the two or more sub-wing areas of the guide member toward an underside of the mold member.

4. The method of claim 2, wherein
in the preparing of the guide member, the guide member comprises:
a guide support layer comprising the main support area and the two or more sub-wing areas;
a guide adhesive layer on the guide support layer; and
a cover layer covering the two or more sub-wing areas,
in the attaching of the display panel onto the guide member, the display panel is attached to the main support area of the guide adhesive layer, and
in the transforming of the guide member, the two or more sub-wing areas are accommodated under the guide support layer and overlap the main support area.

5. The method of claim 4, wherein the guide adhesive layer comprises a curing material different from that of the transparent adhesive layer.

6. The method of claim 4, wherein the separating of the guide member from the display panel comprises softening the guide adhesive layer, and delaminating the guide adhesive layer and the guide support layer from the display panel.

7. The method of claim 2, wherein in the preparing of the guide member, the guide member comprises:
a guide support layer comprising the main support area and the two or more sub-wing areas;
a guide adhesive layer on the main support area of the guide support layer;
an additional support layer on the guide adhesive layer; and
an additional adhesive layer on the additional support layer, and
in the attaching of the display panel onto the guide member, the display panel is attached to the additional adhesive layer.

8. The method of claim 7, wherein the guide adhesive layer comprises a curing material different from that of the transparent adhesive layer, and
the additional adhesive layer comprises a curing material different from that of each of the transparent adhesive layer and the guide adhesive layer.

9. The method of claim 8, wherein the transforming of the guide member comprises softening the guide adhesive layer, and delaminating the guide adhesive layer and the guide support layer from the display panel.

10. The method of claim 8, wherein the separating of the guide member from the display panel comprises softening the additional adhesive layer, and delaminating the additional adhesive layer and the additional support layer from the display panel.

11. The method of claim 7,
wherein the substrate comprises a main region comprising the flat display area and the curved area, and an edge of the main region comprises:
a first side and a second side extending in a first direction and opposing each other in a second direction intersecting the first direction;
a third side and a fourth side extending in the second direction and opposing each other in the first direction; and
corners connecting one of the first and/or second sides to one of the third and/or fourth sides,
wherein each of the additional support layer and the additional adhesive layer comprises:
residual portions overlapping areas of the main region adjacent to the corners; and
a dummy portion overlapping a remaining area excluding the areas of the main region and spaced from the residual portions,
wherein the guide adhesive layer comprises a curing material different from that of the transparent adhesive layer,
wherein the dummy portion of the additional adhesive layer comprises the same curing material as that of the guide adhesive layer, and
wherein the residual portions of the additional adhesive layer comprise a curing material different from that of each of the transparent adhesive layer and the guide adhesive layer.

12. The method of claim 11, wherein the transforming of the guide member comprises softening the guide adhesive layer and the dummy portion of the additional adhesive layer, and delaminating the guide adhesive layer, the guide support layer, the dummy portion of the additional adhesive layer and the dummy portion of the additional support layer from the display panel.

13. The method of claim 11, wherein the separating of the guide member from the display panel comprises softening the residual portions of the additional adhesive layer, and delaminating the residual portions of each of the additional adhesive layer and the additional support layer from the display panel.

14. The method of claim 11,
wherein the flat display area comprises:
a fifth side and a sixth side extending in the first direction and opposing each other in the first direction; and
a seventh side and an eighth side extending in the second direction and opposing each other in the first direction,
wherein the curved area comprises:
a first side area between the first side and the fifth side;
a second side area between the second side and the sixth side;
a third side area between the third side and the seventh side;
a fourth side area between the fourth side and the eighth side;
a first corner area in contact with a vertex between the fifth side and the seventh side and between the first side area and the third side area;
a second corner area in contact with a vertex between the sixth side and the seventh side and between the second side area and the third side area;
a third corner area in contact with a vertex between the sixth side and the eighth side and between the second side area and the fourth side area; and
a fourth corner area in contact with a vertex between the fifth side and the eighth side and between the first side area and the fourth side area.

15. The method of claim 14, wherein the residual portions overlap the first corner area, the second corner area, the third corner area, and the fourth corner area.

16. A display device comprising:
a substrate having a flat display area having a planar shape; and a curved area around the flat display area and having a curved shape;
a circuit layer on the substrate; and
an element layer on the circuit layer, the element layer comprising light emitting elements in emission areas to emit light,
wherein the curved area comprises a peripheral display area around the flat display area and a non-display area around the peripheral display area; and
wherein the display panel is manufactured by:
preparing the display panel having a flat plate shape that is configured to emit light for image display;
preparing a guide member comprising a main support area overlapping the display panel and two or more sub-wing areas extending from an edge of the main support area;
attaching the display panel onto the guide member;
placing a mold member below the guide member;
transforming the display panel from the flat plate shape into a shape with a curved edge by utilizing the guide member and the mold member;
disposing a transparent adhesive material and a cover window on the display panel;
transforming the guide member;
curing the transparent adhesive material to form a transparent adhesive layer that fixes the display panel to the cover window; and
separating the guide member from the display panel.

17. The display device of claim 16, wherein the guide member comprises:
a guide support layer comprising the main support area and the two or more sub-wing areas; and
a guide adhesive layer on the main support area of the guide support layer, and
wherein the guide adhesive layer comprises a curing material different from that of the transparent adhesive layer, and
wherein the method is for manufacturing a display device.

18. An electronic device comprising:
a display panel comprising:
a substrate having a flat display area having a planar shape; and a curved area around the flat display area and having a curved shape;
a circuit layer on the substrate; and
an element layer on the circuit layer, the element layer comprising light emitting elements in emission areas to emit light,
wherein the curved area comprises a peripheral display area around the flat display area and a non-display area around the peripheral display area; and
wherein the display panel is manufactured by:
preparing the display panel having a flat plate shape that is configured to emit light for image display;
preparing a guide member comprising a main support area overlapping the display panel and two or more sub-wing areas extending from an edge of the main support area;
attaching the display panel onto the guide member;
placing a mold member below the guide member;
transforming the display panel from the flat plate shape into a shape with a curved edge by utilizing the guide member and the mold member;
disposing a transparent adhesive material and a cover window on the display panel;
transforming the guide member;
curing the transparent adhesive material to form a transparent adhesive layer that fixes the display panel to the cover window; and
separating the guide member from the display panel.

19. The electronic device of claim 18, wherein the two or more sub-wing areas comprise:
one or more first sub-wing areas extending from one edge of the main support area; and
one or more second sub-wing areas extending from another edge of the main support area that is opposite to the one or more first sub-wing areas, and
the transforming of the display panel comprises pulling the two or more sub-wing areas of the guide member toward an underside of the mold member.

20. The electronic device of claim 18, wherein the electronic device comprises a television, a laptop computer, a monitor, a billboard, an Internet-of-Things (IOT) device, a mobile phone, a smartphone, a tablet personal computer (PC), a smart watch, a watch phone, a mobile communication terminal, an electronic notebook, an electronic book, a portable multimedia player (PMP), a navigation device, an ultra-mobile PC (UMPC) or a car display.
